(19) United States
(12) Patent Application Publication
(10) Pub. No.: US 2016/0308089 A1
(43) Pub. Date: Oct. 20, 2016

(54) METHOD OF MANUFACTURING SEMICONDUCTOR LIGHT EMITTING DEVICE PACKAGE

(71) Applicant: Samsung Electronics Co., Ltd., Suwon-si (KR)

(72) Inventors: Hyung Kun KIM, Suwon-si (KR); Si Han KIM, Seoul (KR); Yu Seung KIM, Seoul (KR); Jung Jin KIM, Hwaseong-si (KR)

(21) Appl. No.: 14/993,066

(22) Filed: Jan. 11, 2016

(30) Foreign Application Priority Data
Apr. 17, 2015 (KR) 10-2015-0054630

(51) Int. Cl. H01L 33/00; H01L 33/54; H01L 33/20; H01L 33/50

(52) U.S. Cl. CPC H01L 33/0095; H01L 33/504; H01L 33/54; H01L 33/20; H01L 2933/0033; H01L 2933/0041; H01L 2933/005

(57) ABSTRACT

Method of manufacturing a semiconductor light emitting device package are described. Semiconductor light emitting device packages includes may be formed by forming a plurality of light emitting diode chips having a structure in which a first conductivity-type semiconductor layer, an active layer, and a second conductivity-type semiconductor layer are sequentially stacked on a wafer, forming a phosphor layer and an encapsulation layer on the first conductivity-type semiconductor layer, forming a texture on the encapsulation layer by removing a portion of the encapsulation layer from an upper surface thereof; and separating the plurality of light emitting diode chips from each other.

### CROSS-REFERENCE TO RELATED APPLICATION

This application claims the priority and benefit of Korean Patent Application No. 10-2015-0054630 filed on Apr. 17, 2015, with the Korean Intellectual Property Office, the disclosure of which is incorporated herein by reference.

### BACKGROUND

Example embodiments described herein relate to methods of manufacturing semiconductor light emitting device packages.

Semiconductor light emitting devices are light sources emitting light as electrons and holes are recombined therein when electrical energy is applied thereto. Such semiconductor light emitting devices are widely used due to desirable characteristics thereof, such as low power consumption, high levels of brightness, compact size, and the like.

Light emitted by a semiconductor light emitting device may pass through all layers of a semiconductor light emitting device package. In a case in which light passes from a layer having a relatively high refractive index to a layer having a relatively low refractive index, the light may be totally internally reflected within the semiconductor light emitting device package and the light extraction efficiency of the semiconductor light emitting device may be reduced.

Thus, a method of improving light extraction efficiency of a semiconductor light emitting device package is required.

### SUMMARY

Example embodiments of the inventive concept can be characterized as providing a method of manufacturing a semiconductor light emitting device having improved light extraction efficiency.

According to one example embodiment, a method of manufacturing a semiconductor light emitting device package may include forming a plurality of light emitting diode chips having a first conductivity-type semiconductor layer, an active layer, and a second conductivity-type semiconductor layer sequentially stacked on a substrate, forming a phosphor layer and an encapsulation layer on the first conductivity-type semiconductor layer, forming a texture on the encapsulation layer by etching an upper surface of the encapsulation layer, and separating the plurality of light emitting diode chips from each other.

According to another example embodiment, a method of manufacturing a semiconductor light emitting device package may include forming a plurality of light emitting diode chips having a first conductivity-type semiconductor layer, an active layer, and a second conductivity-type semiconductor layer sequentially stacked on a substrate, forming a phosphor layer and an encapsulation layer on the first conductivity-type semiconductor layer, forming a texture on an upper surface of the encapsulation layer using a blade, and separating the plurality of light emitting diode chips from each other.

According to another example embodiment, a method of manufacturing a semiconductor light emitting device package may include forming a plurality of light emitting diode chips on a first substrate, bonding a first surface of the plurality of light emitting diode chips to a second substrate, and removing the first substrate from the plurality of light emitting diode chips, thereby exposing a second surface of the plurality of light emitting diode chips such that the second surface is opposite the first surface. The method may further include forming a wavelength conversion material and an encapsulation layer on the second surface of the plurality of light emitting diode chips, removing a portion of the material forming the encapsulation layer to form an encapsulation base layer and a plurality of patterns extending from the encapsulation base layer, and separating the plurality of light emitting diode chips from each other and dividing the encapsulation base layer.

### BRIEF DESCRIPTION OF DRAWINGS

The above and other example embodiments, features and advantages will be more clearly understood from the following detailed description taken in conjunction with the accompanying drawings, in which:

FIG. 1 is a perspective view of a semiconductor light emitting device package according to an example embodiment of the present inventive concept;

FIG. 2 is a cross-sectional view of the semiconductor light emitting device package taken along line A-A′ of FIG. 1;

FIGS. 3A through 3L illustrate a method of manufacturing a semiconductor light emitting device package according to an example embodiment of the present inventive concept;

FIG. 4 is a perspective view of a semiconductor light emitting device package according to another example embodiment of the present inventive concept;

FIGS. 5 through 9 are cross-sectional views of a semiconductor light emitting device package according to other example embodiments of the present inventive concept;

FIG. 10 is a cross-sectional view illustrating an interconnected bump, which may be employed by a semiconductor light emitting device package, according to an example embodiment of the present inventive concept;

FIG. 11 schematically illustrates a white light source module including a semiconductor light emitting device package, according to an example embodiment of the present inventive concept;

FIG. 12 illustrates a CIE color space chromaticity diagram provided to describe a wavelength conversion material which may be employed by a semiconductor light emitting device package according to an example embodiment of the present inventive concept;

FIG. 13 is a cross-sectional view of a quantum dot, which may be employed by a semiconductor light emitting device package according to an example embodiment of the present inventive concept;

FIG. 14 is a perspective view of a backlight unit including a semiconductor light emitting device package, according to an example embodiment of the present inventive concept;

FIG. 15 is a cross-sectional view of a direct-type backlight unit including a semiconductor light emitting device package, according to an example embodiment of the present inventive concept;

FIG. 16 is a plan view illustrating arrangement of light sources of a direct-type backlight unit including a semiconductor light emitting device package, according to another example embodiment of the present inventive concept;

FIG. 17 is a cross-sectional view of a direct-type backlight unit including a semiconductor light emitting device package, according to an example embodiment of the present inventive concept;

FIG. 18 schematically illustrates an optical device including a semiconductor light emitting device package, according to an example embodiment of the present inventive concept;

FIG. 19 is a cross-sectional view of a direct-type backlight unit including a semiconductor light emitting device package, according to another example embodiment of the present inventive concept;

FIGS. 20, 21A and 21B are cross-sectional views of backlight units including a semiconductor light emitting device package, according to other example embodiments of the present inventive concept;

FIG. 22 is an exploded perspective view of a display device including a semiconductor light emitting device package, according to an example embodiment of the present inventive concept;

FIG. 23 is a perspective view of a flat plate lighting device including a semiconductor light emitting device package, according to an example embodiment of the present inventive concept;

FIG. 24 is an exploded perspective view of a lamp including a semiconductor light emitting device package according to an example embodiment of the present inventive concept;

FIG. 25 is an exploded perspective view of a lamp including a semiconductor light emitting device package and a communications module, according to another example embodiment of the present inventive concept;

FIG. 26 is an exploded perspective view of a bar-type lamp including a semiconductor light emitting device package, according to an example embodiment of the present inventive concept;

FIG. 27 is a view schematically illustrating an indoor lighting-controlling network system including a semiconductor light emitting device package, according to an example embodiment of the present inventive concept;

FIG. 28 is a view schematically illustrating an open network system including a semiconductor light emitting device package, according to an example embodiment of the present inventive concept; and

FIG. 29 is a block diagram illustrating communications operations between a smart engine and a mobile device illustrated in FIG. 28.

### DETAILED DESCRIPTION

Example embodiments of the present inventive concept will now be described in detail with reference to the accompanying drawings. These embodiments may, however, be exemplified in many different forms and should not be construed as being limited to the specific embodiments set forth herein. Rather, these embodiments are provided so that this disclosure will be thorough and complete, and will fully convey the scope of the disclosure to those skilled in the art.

In the drawings, the shapes and dimensions of elements may be exaggerated for clarity, and the same reference numerals will be used throughout to designate the same or like elements.

Spatially relative terms, such as “above”, “upper”, “below”, “lower”, “left”, “right” and the like, may be used herein to describe the relationship of one element or feature to another element(s) or feature(s) as illustrated in the figures. It will be understood that the spatially relative terms are intended to encompass different orientations of a device in use or operation, in addition to the orientation depicted in the figures. For example, if the device in the figures is turned over, elements described as “above” other elements or features would then be oriented “below” the other elements or features. Thus, the spatially relative term “above” can encompass both an orientation of above and below. An element may be otherwise oriented (rotated 90 degrees or at other orientations), and the spatially relative descriptors used herein may be interpreted accordingly.

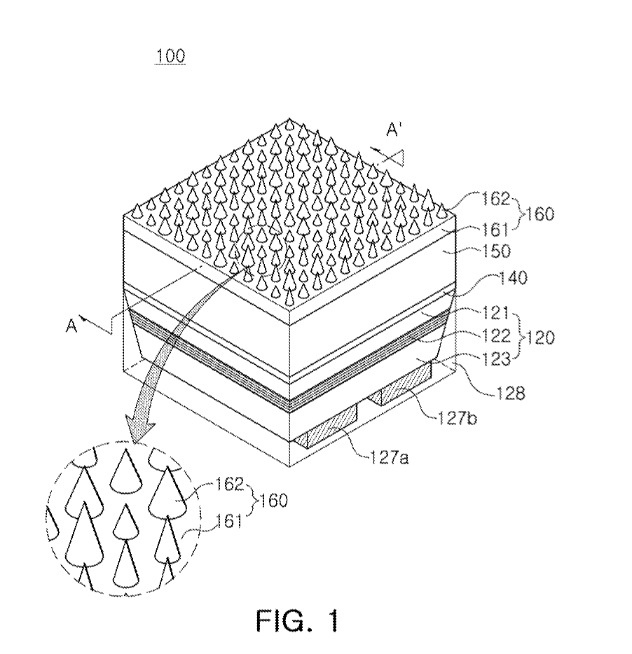

FIG. 1 is a perspective view of a semiconductor light emitting device package according to an example embodiment of the present inventive concept.

Referring to FIG. 1, a semiconductor light emitting device package 100 may have a structure in which a transparent insertion layer 140, a phosphor layer 150, and an encapsulation layer 160 are sequentially stacked on a light emitting stack 120, which includes a first conductivity-type semiconductor layer 121, an active layer 122, and a second conductivity-type semiconductor layer 123. A first metal post 127a and a second metal post 127b may be disposed below the light emitting stack 120. A side encapsulant 128 may cover side surfaces of the light emitting stack 120, the first metal post 127a, and the second metal post 127b.

An upper surface of the encapsulation layer 160 may be textured. For example, the encapsulation layer 160 may include an encapsulation base layer 161 and a plurality of patterns 162 disposed on the encapsulation base layer 161. Each of the plurality of patterns 162 may have a conical structure (or a structure otherwise resembling that of a cone). A width diameter of a bottom side of a conical structure may be different from a diameter of a bottom side of another conical structure, and/or a height of a conical structure may be different from a height of another conical structure.

The first conductivity-type semiconductor layer 121 may be a nitride semiconductor layer (e.g., InₓAl_{y}Ga_{1-x-y}N, where 0≦x<1, 0≦y<1, and 0≦x+y<1) doped with an N-type impurity such as silicon. For example, the first conductivity-type semiconductor layer 121 may include N-type GaN.

The active layer 122 may have a multiple quantum well (MQW) structure in which a quantum well layer and a quantum barrier layer are alternately stacked. For example, each of the quantum well layer and the quantum barrier layer may be formed of InₓAl_{y}Ga_{1-x-y}N (where 0≦x≦1, 0≦y≦1, and 0≦x+y≦1), but have different compositions. For example, the quantum well layer may be InₓGa₁₋ₓN (0<x≦1), and the quantum barrier layer may be GaN or AlGaN. Respective thicknesses of the quantum well layer and the quantum barrier layer may range from 1 nm to 50 nm. A structure of the active layer 122 need not be limited to the multiple quantum well structure, and may be a single quantum well structure.

The second conductivity-type semiconductor layer 123 may be a nitride semiconductor layer (e.g., InₓAl_{y}Ga_{1-x-y}N, where 0≦x<1, 0≦y<1, and 0≦x+y<1) doped with a P-type impurity such as magnesium (Mg).

A refractive index of the transparent insertion layer 140 may be higher than a refractive index of the phosphor layer 150 and lower than a refractive index of the first conductivity-type semiconductor layer 121. Accordingly, total internal reflection of light emitted by the light emitting stack 120 may be reduced. The transparent insertion layer 140 may be, for example, a silicone layer.

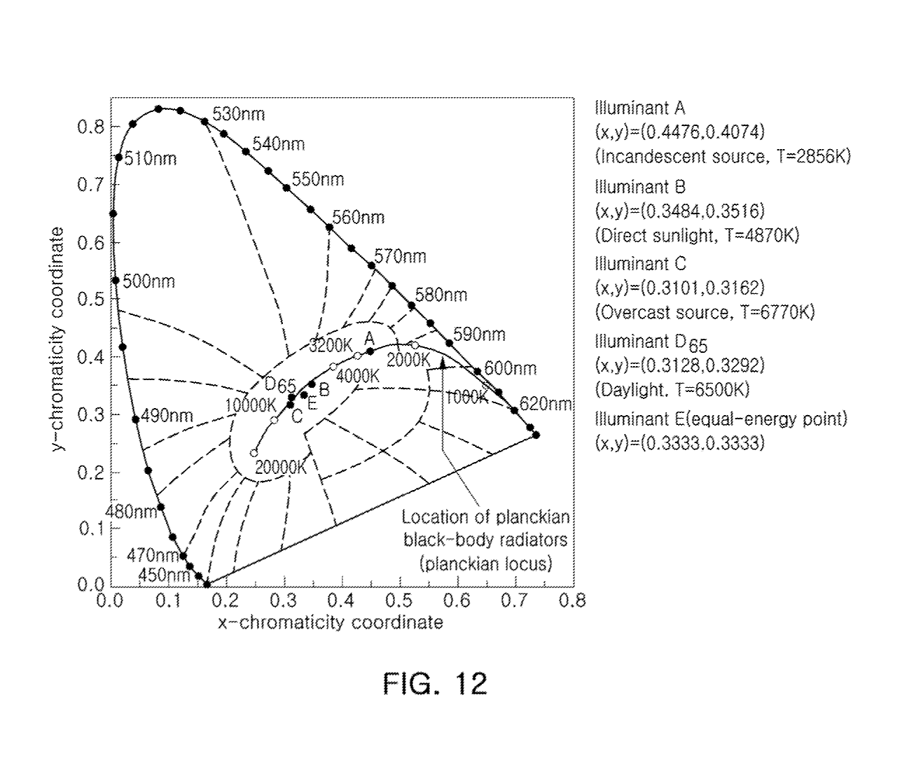

The phosphor layer 150 may be provided as a transparent resin containing phosphor particles diffused therein. If the diameter of phosphor particles contained in the phosphor layer 150 is less than the thickness of the transparent insertion layer 140, then total internal reflection of the light emitted by the light emitting stack 120 may occur inside the transparent insertion layer 140. Therefore the diameter of phosphor particles contained in the phosphor layer 150 may, in one embodiment, be greater than the thickness of the transparent insertion layer 140. An exemplary description of phosphor particles contained in the phosphor layer 150 is provided with respect to FIG. 12.

A level of a refractive index of the encapsulation layer 160 may be between a refractive index of the phosphor layer 150 and a refractive index of air. Accordingly, light scattering after colliding with phosphor particles contained in the phosphor layer 150 may be easily emitted into the air.

Light extraction efficiency of light emitted by the light emitting stack 120 may be increased due to the plurality of patterns 162 formed on the encapsulation base layer 161. The encapsulation layer 160 may be provided as, for example, a layer of epoxy resin material, silicone resin material, or the like. In one embodiment, the encapsulation layer 160 may be provided as a layer of polydimethylsiloxane material.

The side encapsulant 128 may have a sufficiently high Young's modulus so as to support a light emitting diode chip. The side encapsulant 128 may have a sufficiently high thermal conductivity to release heat generated in the light emitting stack 120. The side encapsulant 128 may include a light reflective material to reflect light emitted toward a side surface of the light emitting stack 120. The light reflective material may be, for example, titanium dioxide (TiO₂), aluminum oxide (Al₂O₃), or the like.

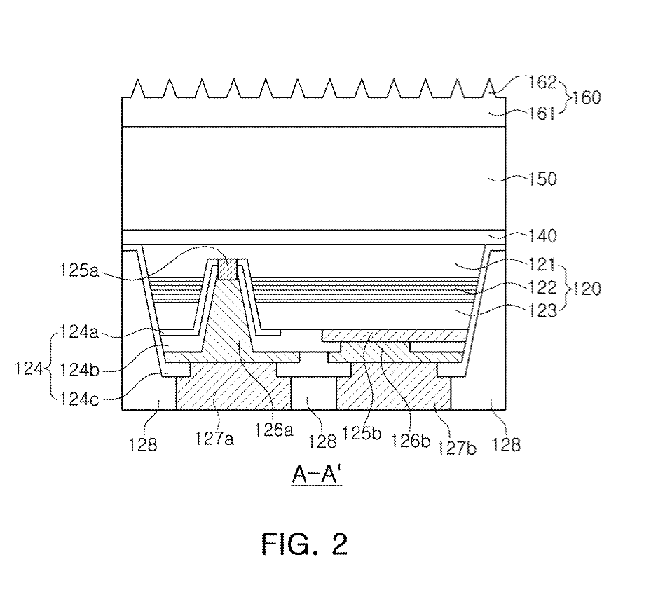

FIG. 2 is a cross-sectional view of the semiconductor light emitting device package taken along line A-A′ of FIG. 1.

Referring to FIG. 2, a first electrode 125a electrically connected to a first conductivity-type semiconductor layer 121 may be disposed below the first conductivity-type semiconductor layer 121. A first pad 126a may penetrate through a second conductivity-type semiconductor layer 123 and an active layer 122 to be electrically connected to the first electrode 125a. A first metal post 127a may be disposed below the first pad 126a and may be electrically connected thereto.

A second electrode 125b may be disposed below the second conductivity-type semiconductor layer 123 to be electrically connected to the second conductivity-type semiconductor layer 123. The second electrode 125b may be disposed below a portion of the second conductivity-type semiconductor layer 123 to be insulated from the first conductivity-type semiconductor layer 121 and the active layer 122. A second pad 126b may be disposed below the second electrode 125b to be electrically connected thereto. A second metal post 127b may be disposed below the second pad 126b to be electrically connected thereto.

An insulating material layer 124 may be disposed between the electrodes, pads, and metal posts so that the electrodes, pads, and metal posts can be electrically insulated from each other. The insulating material layer 124 may include a first insulation layer 124a, a second insulation layer 124b, and a third insulation layer 124c.

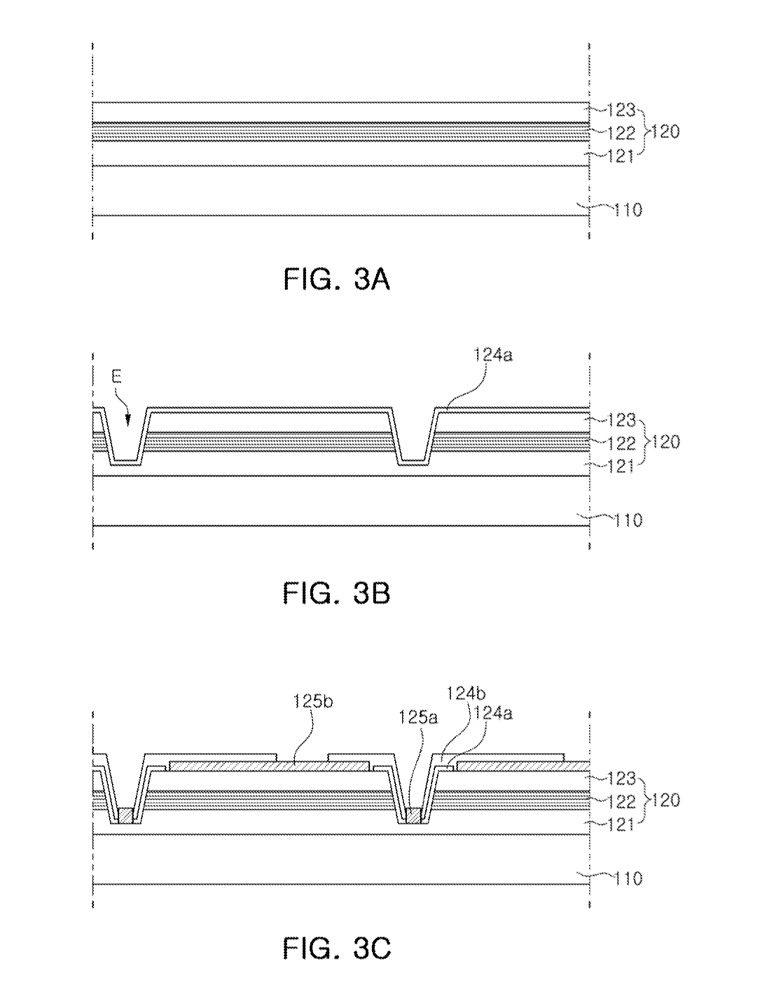

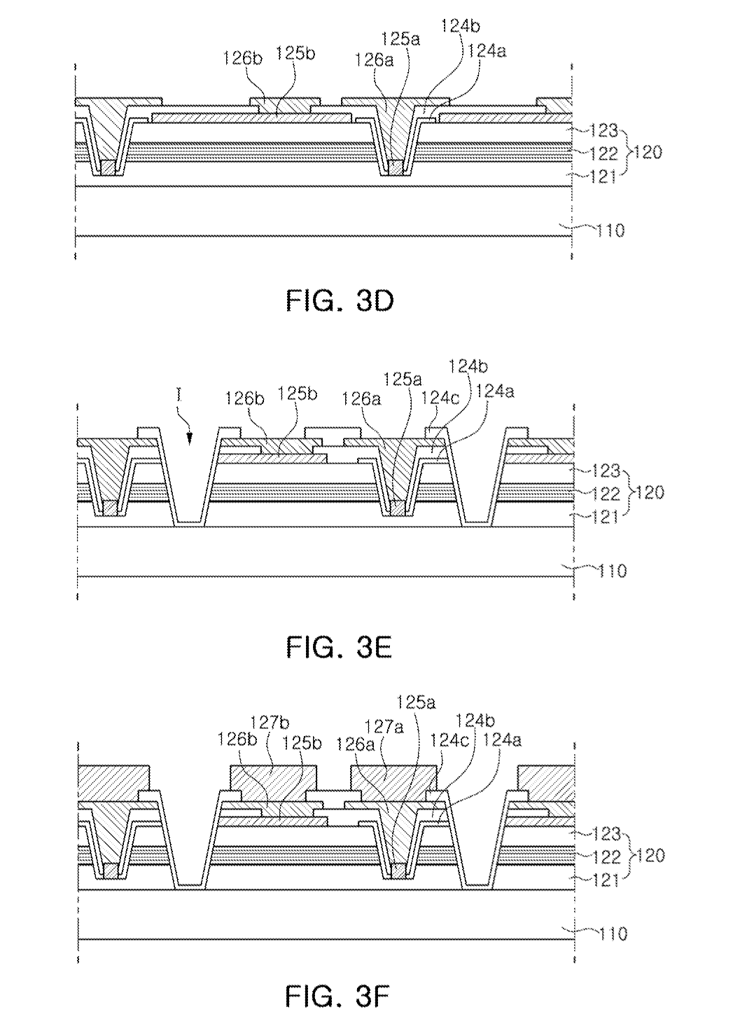

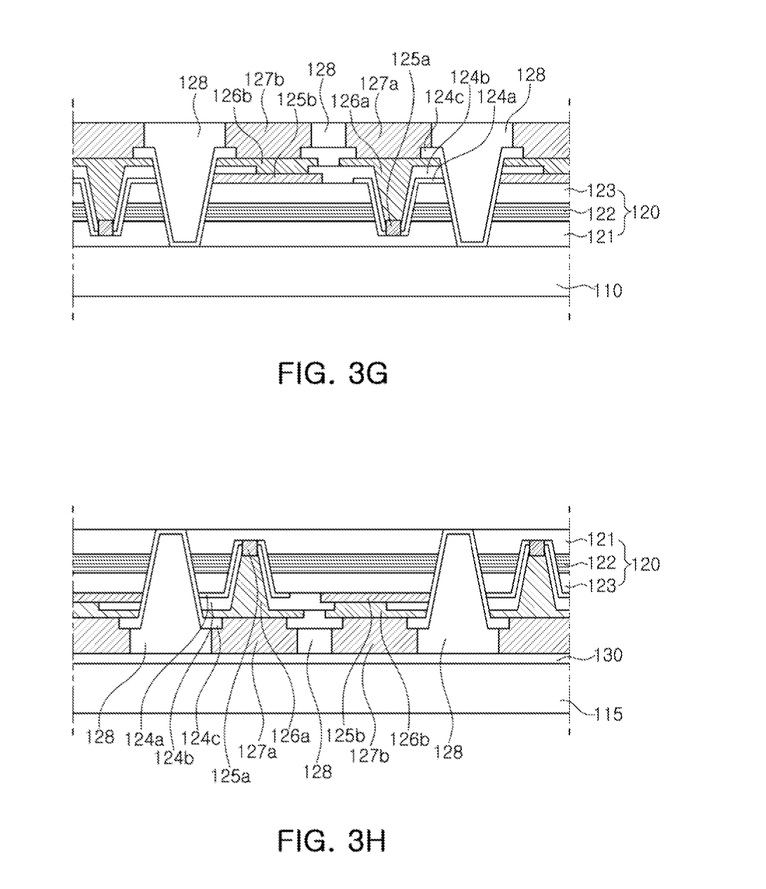

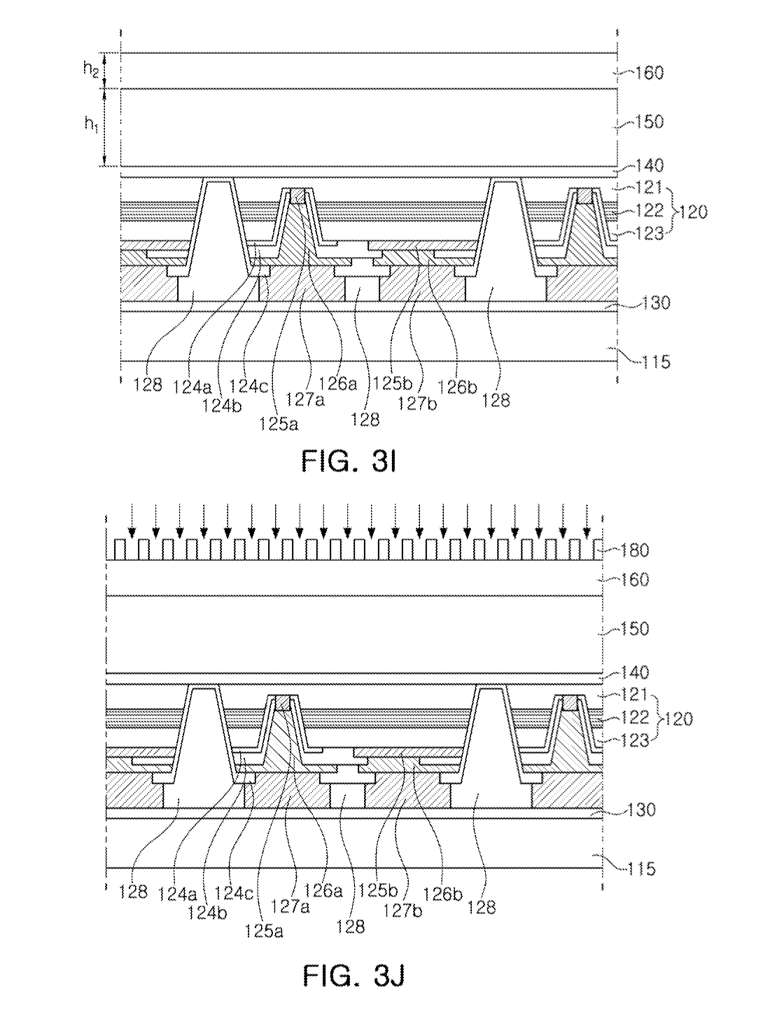

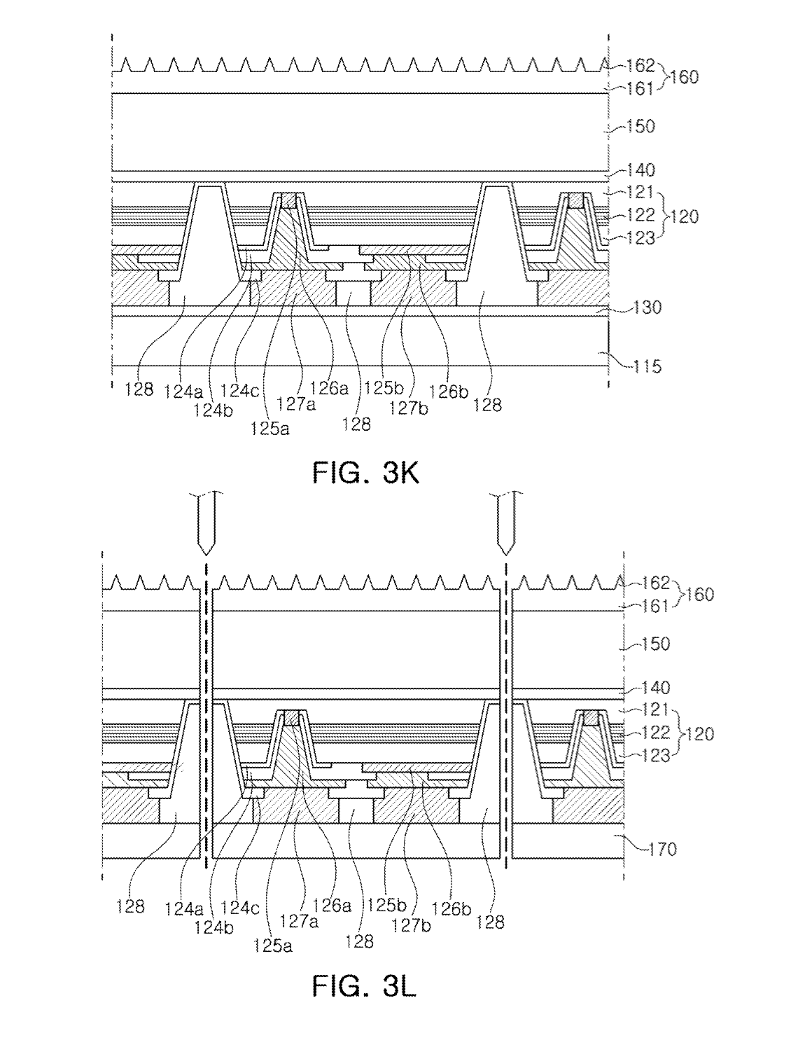

The first insulation layer 124a may be disposed on a side surface of an open portion E (see FIG. 3B) so that the first electrode 125a can be electrically insulated from the active layer 122 and the second conductivity-type semiconductor layer 123. The second insulation layer 124b may be disposed between the first pad 126a and the second pad 126b so that the first pad 126a and the second pad 126b can be electrically insulated from each other. The third insulation layer 124c may be disposed between the first metal post 127a and the second metal post 127b so that the first metal post 127a and the second metal post 127b can be electrically insulated from each other. The third insulation layer 124c may also be disposed on a side surface of a light emitting stack 120.

FIGS. 3A through 3L illustrate a method of manufacturing the semiconductor light emitting device packages of FIG. 1 and FIG. 2.

Referring to FIG. 3A, a light emitting stack 120 having a structure in which a first conductivity-type semiconductor layer 121, an active layer 122, and a second conductivity-type semiconductor layer 123 are sequentially stacked on a substrate 110. In one embodiment, the light emitting stack may be formed at a wafer level.

The substrate 110 may be provided as an insulating substrate (e.g., a sapphire substrate, MgAl₂O₄, MgO, LiAlO₂, LiGaO₂, etc.), a conductive substrate, a semiconductive substrate (e.g., a substrate formed of SiC, Si, GaN, or the like), or any combination thereof. Referring to FIG. 3B, an open portion E may be formed in the light emitting stack 120 so that a portion of the first conductivity-type semiconductor layer 121 can be exposed, and then the first insulation layer 124a may be deposited. One or more open portions E may be formed in a light emitting device package.

Referring to FIG. 3C, portions of the first insulation layer 124a can be removed to expose regions of the first conductivity-type semiconductor layer 121 and the second conductivity-type semiconductor layer 122. Thereafter, the first electrode 125a may be deposited may be deposited so as to electrically contact first insulation layer 124a, and the second electrode 125b may be deposited so as to electrically contact the second conductivity-type semiconductor layer 123. As illustrated, the first electrode 125a and the second electrode 125b are electrically insulated from each other. Subsequently, a second insulation layer 124b may be formed over and between the first electrode 125a and the second electrode 125b.

The first electrode 125a and the second electrode 125b may be provided as reflective electrodes containing at least one of Ag, Al, Ni, Cr, Cu, Au, Pd, Pt, Sn, W, Rh, Ir, Ru, Mg, Zn, or the like, or any alloy thereof or other combination thereof.

Referring to FIG. 3D, a first pad 126a and a second pad 126b may be formed on, and electrically connected to, the first electrode 125a and the second electrode 125b, respectively.

Referring to FIG. 3E, one or more isolation trenches I may be formed in order to divide the light emitting stack 120 into a plurality of light emitting diode chips. Each isolation trench I may be formed between the first pad 126a and the second pad 126b to penetrate through the second insulation layer 124b, the second electrode 125b, and the light emitting stack 120. In one embodiment, the isolation trench I does not penetrate into the substrate 110. A third insulation layer 124c may be disposed so as to cover side surfaces of the isolation trench I.

A trench-forming process for forming each isolation trench I is typically performed using a blade, but it will be appreciated that the trench-forming process may be performed using any other suitable technique. Upon forming the one or more isolation trenches I, the light emitting stack 120 is divided into a plurality of light emitting diode chips, which are supported by the substrate 110. The light emitting stack 120 may have a trapezoidal cross-sectional shape during the trench-forming process. The trapezoidal cross-sectional shape may have an upper surface that is shorter than a lower surface, and an inclined surface formed on a side surface of the light emitting stack 120.

Referring to FIG. 3F, a first metal post 127a and a second metal post 127b may be formed on, and electrically connected to, the first pad 126a and the second pad 126b, respectively. The first metal post 127a and the second metal post 127b may be electrically insulated from each other by the third insulation layer 124c.

Referring to FIG. 3G, a side encapsulant 128 may be formed between the first metal post 127a and the second metal post 127b, and in the one or more isolation trenches I (see FIG. 3E). In one embodiment, the side encapsulant 128 is formed by applying an encapsulant material may be applied to upper surfaces of the first metal post 127a and the second metal post 127b to cover the first metal post 127a and the second metal post 127b. Then, the applied encapsulant material may be flattened to expose the first metal post 127a and the second metal post 127b.

Referring to FIG. 3H, a bonding layer 130 may be disposed on a surface of the semiconductor light emitting device package opposite to a surface thereof on which the substrate 110 (see FIG. 3G) has been bonded (e.g., on the first metal post 127a, the second metal post 127b, and the side encapsulant 128), so that a support substrate 115 can be bonded thereto. The bonding layer 130 may be formed of, for example, an ultraviolet curable material. Subsequently, the substrate 110 may be removed using a method such as grinding or laser lift-off. If necessary, the upper surface of the first conductivity-type semiconductor layer 121 may be textured to improve light extraction efficiency.

Referring to FIG. 3I, a transparent insertion layer 140, a phosphor layer 150, and an encapsulation layer 160 may be sequentially stacked on the first conductivity-type semiconductor layer 121. The phosphor layer 150 may contain phosphor particles. A ratio of a thickness of the encapsulation layer 160 to the phosphor layer 150 may be between 1:2 and 1:4. In one embodiment, the ratio of a thickness of the encapsulation layer 160 to the phosphor layer 150 may be 1:3, or thereabout. Although light emitted by the light emitting stack 120 collides with the phosphor particles contained in the phosphor layer 150 and is scattered, the light may be prevented from re-entering the light emitting stack 120 because a thickness h₁ of the phosphor layer 150 is greater than a thickness h₂ of the encapsulation layer 160.

Referring to FIG. 3J, mask patterns 180 are formed on the encapsulation layer 160 and, thereafter, a dry etching process may be performed on the encapsulation layer 160 to form a plurality of patterns 162 (see FIG. 3K). The mask patterns 180 may be formed by applying a photoresist to the encapsulation layer 160 and then performing exposure and development processes on the applied photoresist using a photomask.

Referring to FIG. 3K, the shape and size of a plurality of patterns 162 to be formed by applying a dry etching process to the encapsulation layer 160 may be determined by adjusting a distance between the mask patterns 180 (see FIG. 3J) and the heights thereof.

A dry etching process may be performed, for example, as a reactive ion etching method using a gas mixture of a fluorine-based gas and oxygen, but is not limited thereto. In a case in which the plurality of patterns 162 (see FIG. 3K) are formed using a wet etching process, an adequate etch selectivity ratio of the mask patterns 180 to the encapsulation layer 160 may not be secured, and a chemical deterioration of a light emitting diode chip may occur. Such problems may be prevented from occurring when a dry etching process is used.

Referring to FIG. 3K, a plurality of patterns 162 may be formed from an upper portion of the encapsulation layer 160. The portion of the encapsulation layer 160 remaining after forming the plurality of patterns 162 is herein referred to as the encapsulation base layer 161. Light extraction efficiency of the light emitted by the light emitting stack 120 may be improved by the plurality of patterns 162.

Referring to FIG. 3L, a semiconductor light emitting device package may be formed by cutting the phosphor layer 150, the encapsulation layer 160, the insertion layer 140, third insulation layer 124c, and the side encapsulant 128, thereby singulating the light emitting diode chips. Optionally, prior to cutting the aforementioned materials, the support substrate 115 maybe removed (e.g., by releasing the bonding layer 130 from the first metal post 127a, the second metal post 127b and the side encapsulant 128) and adhesive tape 170 may be attached to the first metal post 127a, the second metal post 127b and the side encapsulant 128.

A chip scale package manufactured using the above process may emit large amount of light per area thereof, because size of the package is substantially the same as the size of a semiconductor light emitting device (or a light emitting diode chip) included therein. In addition, since all the of processes described above are performed at the wafer level, the process is appropriate for mass production, and LED chips may be manufactured integrally with a wavelength conversion material (e.g., a phosphor material) and an optical structure such as a lens.

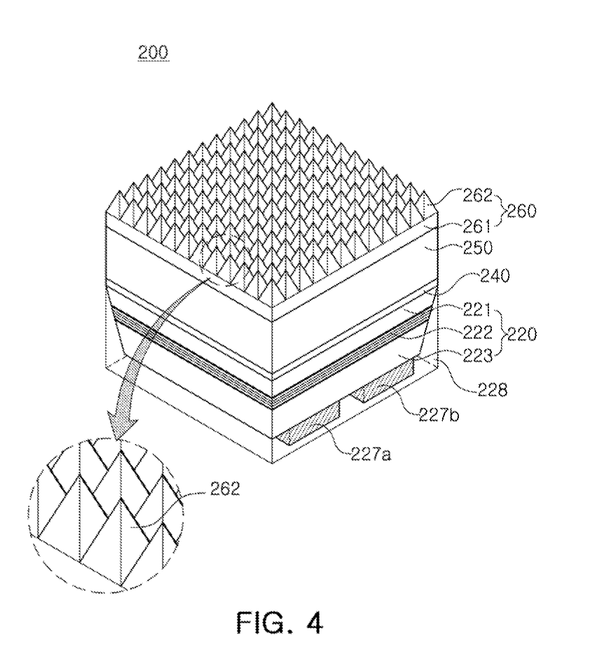

FIG. 4 is a perspective view illustrating a semiconductor light emitting device package according to another example embodiment of the present inventive concept.

Referring to FIG. 4, a semiconductor light emitting device package 200 may have a structure in which a transparent insertion layer 240, a phosphor layer 250, and an encapsulation layer 260 are sequentially stacked on a light emitting stack 220, which includes a first conductivity-type semiconductor layer 221, an active layer 222, and a second conductivity-type semiconductor layer 223. A first metal post 227a and a second metal post 227b may be disposed below the light emitting stack 220. A side encapsulant 228 may cover side surfaces of the light emitting stack 220, the first metal post 227a, and the second metal post 227b.

An upper surface of the encapsulation layer 260 may be textured. For example, the encapsulation layer 260 may include an encapsulation base layer 261 and a plurality of patterns 262 disposed on the encapsulation base layer 261. The plurality of patterns 262 may have a square pyramidal shape. The square pyramidal shape of the plurality of patterns 262 may be formed, for example, by cutting the upper surface of the encapsulation layer 260 with a blade. It will nevertheless be appreciated that any of the plurality of patterns 262 may have a conical shape, a triangular pyramidal shape, a pentagonal pyramidal shape, a hexagonal pyramidal shape, or the like, in addition to (or as an alternative to) the square pyramidal shape shown in FIG. 4.

The first conductivity-type semiconductor layer 221, the active layer 222, the second conductivity-type semiconductor layer 223, the phosphor layer 250, the encapsulation layer 260, and the side encapsulant 228 maybe formed of the same or similar materials as discussed with respect to their counterparts of the semiconductor light emitting device package 100 of FIG. 1.

Table 1 below provides results of a computer simulation of luminance of the light emitting device package 100 of FIG. 1 and the light emitting device package 200 of FIG. 4. In the light emitting device package 100 of FIG. 1, at least one or more conical patterns 162 including patterns having a bottom diameter ranging from 0.01 μm to 0.09 μm, from 0.1 μm to 0.9 μm, or from 1.0 μm to 10 μm, mixed at a specific proportion, are randomly disposed on an upper surface of the encapsulation base layer 161 (see FIG. 1) . Here, heights of the conical patterns 162 (see FIG. 1) may range from 0.1 μm to 50 μm, and a pitch between two adjacent conical patterns may also range from 0.1 μm to 50 μm. For example, the height of a conic pattern may be 1.7 μm, and a pitch between two adjacent conical patterns may be 2.7 μm. In the semiconductor light emitting device package 200 of FIG. 4, pyramidal-shaped patterns 262 (see FIG. 4) having a base width of 2.2 μm are disposed on an upper surface of the encapsulation base layer 261 (see FIG. 4) . Here, a height of the pyramidal-shaped patterns 262 may be 1.7 μm, and a pitch between two adjacent pyramidal-shaped patterns may be 2.7 μm. The reference semiconductor light emitting device package in Table 1 may be from the same as the semiconductor light emitting device package 100 of FIG. 1, but does not include the plurality of patterns 162 (see FIG. 1) formed on an upper surface of the encapsulation layer 160 (see FIG. 1).

TABLE 1

| Semiconductor light emitting | Relative |
|---|---|
| device package | Luminance |
| Reference semiconductor light emitting | 100% |
| device package | |
| Semiconductor light emitting | 103% |
| device package of FIG. 1 | |
| Semiconductor light emitting | 104~104.5% |
| device package of FIG. 4 | |

As provided in Table 1, a semiconductor light emitting device having a textured encapsulation layer may have a greater degree of luminance than a luminance of a semiconductor light emitting device without a textured encapsulation layer. In addition, a semiconductor light emitting device having an encapsulation layer textured with pyramidal-shaped patterns may have a greater luminance than a luminance of a semiconductor light emitting device having an encapsulation layer textured with conical patterns, and may have significantly improved light extraction efficiency due to different shapes of pyramidal patterns.

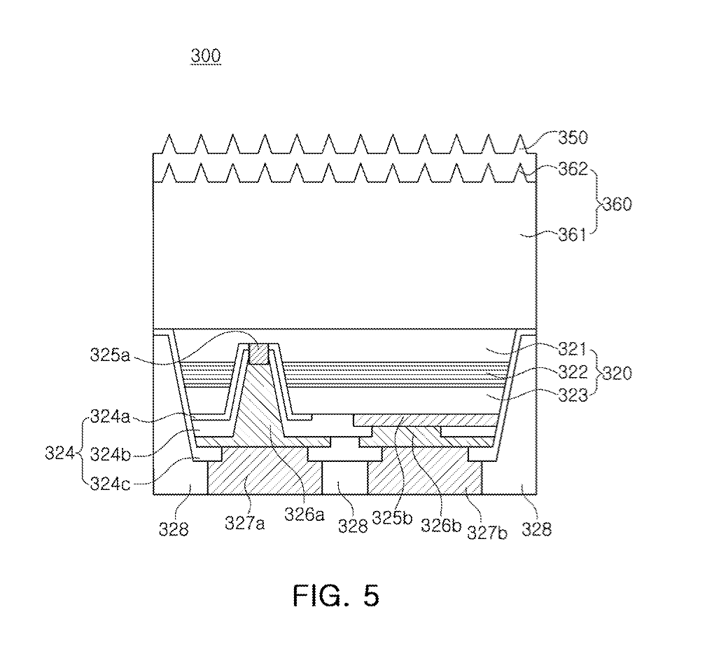

FIG. 5 is a cross-sectional view illustrating a semiconductor light emitting device package according to an example embodiment of the present inventive concept. In FIG. 5, the cross-sectional view shown corresponds to the view taken along the line A-A′ of FIG. 1.

Referring to FIG. 5, a semiconductor light emitting device package 300 may have a structure in which an encapsulation layer 360 and a phosphor layer 350 are sequentially stacked on a light emitting stack 320, which includes a first conductivity-type semiconductor layer 321, an active layer 322, and a second conductivity-type semiconductor layer 323.

An upper surface of the encapsulation layer may be textured. For example, the encapsulation layer 360 may include an encapsulation base layer 361 and a plurality of patterns 362 disposed on the encapsulation base layer 361. The plurality of patterns 362 may have a conical shape (e.g., having equal diameters and heights or different diameters and heights from each other, as discussed above with respect to the semiconductor light emitting device package 100 of FIG. 1), a pyramidal shape (e.g., as discussed above with respect to the semiconductor light emitting device package 200 of FIG. 4), or the like or any combination thereof.

The phosphor layer 350 may be formed on the encapsulation layer 360. A ratio of a thickness of the phosphor layer 350 to the encapsulation layer 360 may be between 1:2 and 1:4. In one embodiment, the ratio of a thickness of the phosphor layer 350 to the encapsulation layer 360 may be 1:3, or thereabout. Although light emitted by a light emitting stack 320 collides with the phosphor particles contained in the phosphor layer 350 and is scattered, the light may be prevented from re-entering the light emitting stack 320 because the encapsulation layer 360 has a greater thickness than the thickness of the phosphor layer 350 and is disposed between the light emitting stack 320 and the phosphor layer 350.

A shape of an upper surface of the phosphor layer 350 may be equal to, or otherwise at least substantially correspond to, a shape of an upper surface of the encapsulation layer 360 having the plurality of patterns 362.

A first electrode 325a electrically connected to a first conductivity-type semiconductor layer 321 may be disposed on the first conductivity-type semiconductor layer 121. A first pad 326a may penetrate through a second conductivity-type semiconductor layer 323 and an active layer 322 to be electrically connected to the first electrode 125a. A first metal post 327a may be disposed below the first pad 326a and electrically connected thereto.

A second electrode 325b may be disposed below the second conductivity-type semiconductor layer 323 to be electrically connected thereto. The second electrode 325b may be disposed below a portion of the second conductivity-type semiconductor layer 323 to be insulated from the first conductivity-type semiconductor layer 321 and the active layer 322. A second pad 326b may be disposed below the second electrode 325b to be electrically connected thereto. A second metal post 327b may be disposed below the second pad to be electrically connected thereto.

An insulating material layer 324 may be disposed between the electrodes, pads, and metal posts so that the electrodes, pads, and metal posts can be electrically insulated from each other. The insulating material layer 324 may include a first insulation layer 324a, a second insulation layer 324b, and a third insulation layer 324c.

The first insulation layer 324a may be disposed on a side surface of an open portion E (see FIG. 3B) so that the first electrode 325a can be insulated from the active layer 322 and the second conductivity-type semiconductor layer 323. The second insulation layer 324b may be disposed between the first pad 326a and the second pad 326b so that the first pad 326a and the second pad 326b can be electrically insulated from each other. The third insulation layer 324c may be disposed between the first metal post 327a and the second metal post 327b so that the first metal post 127a and the second metal post 127b can be electrically insulated from each other. The third insulation layer 324c may also be disposed on a side surface of a light emitting stack 320.

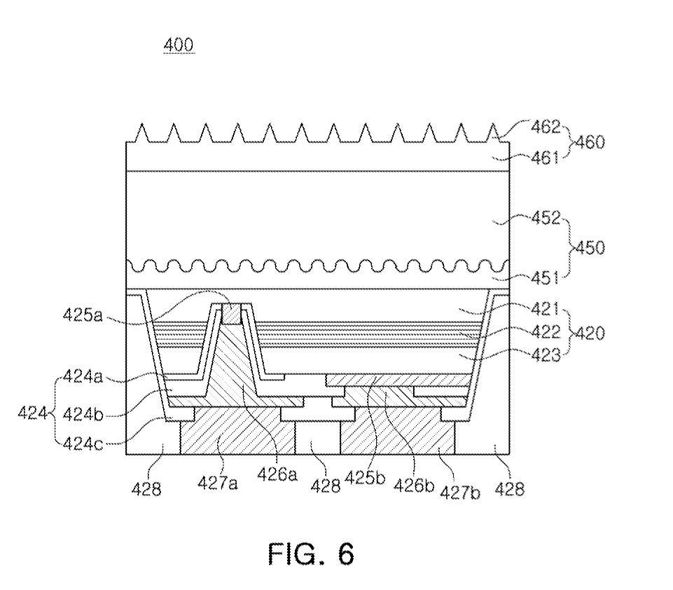

FIG. 6 is a cross-sectional view illustrating a semiconductor light emitting device package according to an example embodiment of the present inventive concept. In FIG. 6, the cross sectional view shown corresponds to the view taken along the line A-A′ of FIG. 1.

Referring to FIG. 6, a semiconductor light emitting device package 400 may have a structure in which a phosphor layer 450 and an encapsulation layer 460 are sequentially stacked on a light emitting stack 420, which includes a first conductivity-type semiconductor layer 421, an active layer 422, and a second conductivity-type semiconductor layer 423.

A ratio of a thickness of the encapsulation layer 460 to the phosphor layer 450 may be between 1:2 and 1:4. In one embodiment, the ratio of the thickness of the encapsulation layer 460 to the phosphor layer 450 may be 1:3, or thereabout.

The phosphor layer 450 may have a structure in which a first phosphor layer 451 and a second phosphor layer 452 are sequentially stacked.

A wavelength of light converted by the first phosphor layer 451 may be longer than a wavelength of light converted by the second phosphor layer 452. For example, when the light emitting stack 420 emits blue light, the first phosphor layer 451 may be a red phosphor layer, and the second phosphor layer 452 may be a green phosphor layer.

A thickness of the first phosphor layer 451 may be smaller than a thickness of the second phosphor layer 452. Phosphor particles contained in the first phosphor layer 451 may be present on an upper surface of the first phosphor layer 451 so that a texture may be formed thereon. Light re-entering the first phosphor layer 451 after colliding with phosphor particles contained in the second phosphor layer 452 may be scattered on a surface of the first phosphor layer 451 due to the texture. Accordingly, light extraction efficiency may be improved.

An upper surface of the encapsulation layer 460 may be textured. The encapsulation layer 460 may include an encapsulation base layer 461 and a plurality of patterns 462 disposed on the encapsulation base layer 461. The plurality of patterns 462 may have a conical shape (e.g., having equal diameters and heights or different diameters and heights from each other, as discussed above with respect to the semiconductor light emitting device package 100 of FIG. 1), a pyramidal shape (e.g., as discussed above with respect to the semiconductor light emitting device package 200 of FIG. 4), or the like or any combination thereof.

A first electrode 425a electrically connected to a first conductivity-type semiconductor layer 421 may be disposed on the first conductivity-type semiconductor layer 421. A first pad 426a may penetrate through a second conductivity-type semiconductor layer 423 and an active layer 422 to be electrically connected to the first electrode 425a. A first metal post 427a may be disposed below the first pad 426a and electrically connected thereto.

A second electrode 425b may be disposed below the second conductivity-type semiconductor layer 423 to be electrically connected thereto. The second electrode 425b may be disposed below a portion of the second conductivity-type semiconductor layer 423 to be insulated from the first conductivity-type semiconductor layer 421 and the active layer 422. A second pad 426b may be disposed below the second electrode 425b to be electrically connected thereto. A second metal post 427b may be disposed below the second pad 426b to be electrically connected thereto.

An insulating material layer 424 may be disposed between the electrodes, pads, and metal posts so that the electrodes, pads, and metal posts can be electrically insulated from each other. The insulating material layer 424 may include a first insulation layer 424a, a second insulation layer 424b, and a third insulation layer 424c.

The first insulation layer 424a may be disposed on a side surface of an open portion E (see FIG. 3B) so that the first electrode 425a can be insulated from the active layer 422 and the second conductivity-type semiconductor layer 423. The second insulation layer 424b may be disposed between the first pad 426a and the second pad 426b so that the first pad 426a and the second pad 426b can be electrically insulated from each other. The third insulation layer 424c may be disposed between the first metal post 427a and the second metal post 427b so that the first metal post 427a and the second metal post 427b can be electrically insulated from each other. The third insulation layer 424c may also be disposed on a side surface of a light emitting stack 420.

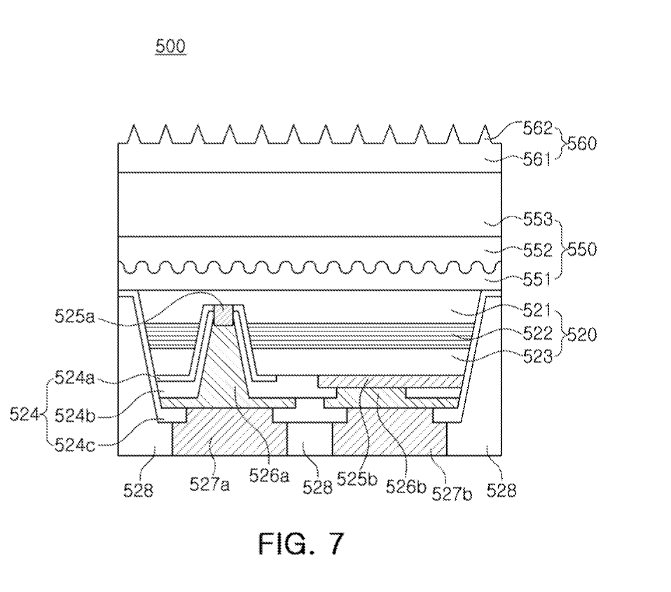

FIG. 7 is a cross-sectional view illustrating a semiconductor light emitting device package according to an example embodiment of the present inventive concept. In FIG. 7, the cross sectional view shown corresponds to the view taken along the line A-A′ of FIG. 1.

Referring to FIG. 7, a semiconductor light emitting device package 500 may have a structure in which a phosphor layer 550 and an encapsulation layer 560 are sequentially stacked on a light emitting stack 520, which includes a first conductivity-type semiconductor layer 521, an active layer 522, and a second conductivity-type semiconductor layer 523. A ratio of a thickness of the encapsulation layer 560 to the phosphor layer 550 may be between 1:2 and 1:4. In one embodiment, the ratio of a thickness of the encapsulation layer 560 to the phosphor layer 550 may be 1:3, or thereabout.

The phosphor layer 550 may have a structure in which a first phosphor layer 551, a second phosphor layer 552, and a third phosphor layer 553 are sequentially stacked.

A wavelength of light converted by the first phosphor layer 551 may be longer than a wavelength of light converted by the second phosphor layer 552, and a wavelength of light converted by the second phosphor layer 552 may be longer than a wavelength of light converted by the third phosphor layer 553. For example, when the light emitting stack 520 emits ultraviolet light, the first phosphor layer 551 may be a red phosphor layer, the second phosphor layer 552 may be a green phosphor layer, and the third phosphor layer 553 may be a blue phosphor layer.

A thickness of the first phosphor layer 551 may be smaller than a thickness of the second phosphor layer 552 and a thickness of the third phosphor layer 553. Phosphor particles contained in the first phosphor layer 551 may be present on an upper surface of the first phosphor layer 551 so that a texture can be formed thereon. Light re-entering the first phosphor layer 551 after colliding with phosphor particles contained in the second phosphor layer 552 and the third phosphor layer 553 may be scattered on a surface of the first phosphor layer 551 due to the texture. Accordingly, light extraction efficiency may be improved.

An upper surface of the encapsulation layer 560 may be textured. The encapsulation layer 560 may include an encapsulation base layer 561 and a plurality of patterns 562 disposed on the encapsulation base layer 561. The plurality of patterns 462 may have a conical shape (e.g., having equal diameters and heights or different diameters and heights from each other, as discussed above with respect to the semiconductor light emitting device package 100 of FIG. 1), a pyramidal shape (e.g., as discussed above with respect to the semiconductor light emitting device package 200 of FIG. 4), or the like or any combination thereof.

A first electrode 525a electrically connected to a first conductivity-type semiconductor layer 521 may be disposed on the first conductivity-type semiconductor layer 521. A first pad 526a may penetrate through a second conductivity-type semiconductor layer 523 and an active layer 522 to be electrically connected to the first electrode 525a. A first metal post 527a may be disposed below the first pad 526a and electrically connected thereto.

A second electrode 525b may be disposed below the second conductivity-type semiconductor layer 523 to be electrically connected thereto. The second electrode 525b may be disposed below a portion of the second conductivity-type semiconductor layer 523 to be insulated from the first conductivity-type semiconductor layer 521 and the active layer 522. A second pad 526b may be disposed below the second electrode 525b to be electrically connected thereto. A second metal post 527b may be disposed below the second pad 526b to be electrically connected thereto.

An insulating material layer 524 may be disposed between the electrodes, pads, and metal posts so that the electrodes, pads, and metal posts can be electrically insulated from each other. The insulating material layer 524 may include a first insulation layer 524a, a second insulation layer 524b, and a third insulation layer 524c.

The first insulation layer 524a may be disposed on a side surface of an open portion E (see FIG. 3B) so that the first electrode 525a can be electrically insulated from the active layer 522 and the second conductivity-type semiconductor layer 523. The second insulation layer 524b may be disposed between the first pad 526a and the second pad 526b so that the first pad 526a and the second pad 526b can be electrically insulated from each other. The third insulation layer 524c may be disposed between the first metal post 527a and the second metal post 527b so that the first metal post 527a and the second metal post 527b can be electrically insulated from each other. The third insulation layer 524c may also be disposed on a side surface of a light emitting stack 520.

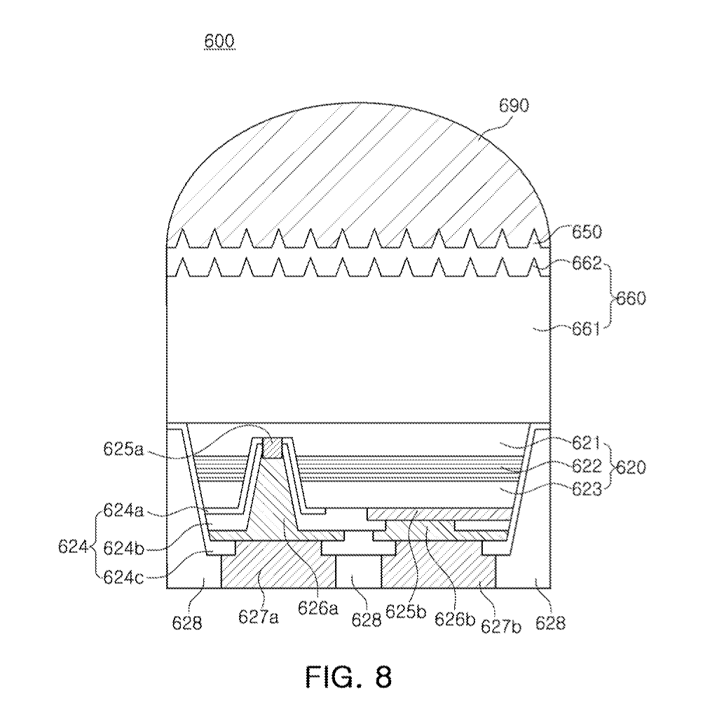

FIG. 8 is a cross-sectional view illustrating a semiconductor light emitting device package according to an example embodiment of the present inventive concept. In FIG. 8, the cross sectional view shown corresponds to the view taken along the line A-A′ of FIG. 1.

Referring to FIG. 8, a semiconductor light emitting device package 600 may have a structure in which an encapsulation layer 660, a phosphor layer 650, and a lens 690 are sequentially stacked on a light emitting stack 620, which includes a first conductivity-type semiconductor layer 621, an active layer 622, and a second conductivity-type semiconductor layer 623.

An upper surface of the encapsulation layer 660 may be textured. The encapsulation layer 660 may include an encapsulation base layer 661 and a plurality of patterns 662 disposed on the encapsulation base layer 661. The plurality of patterns 662 may have a conical shape (e.g., having equal diameters and heights or different diameters and heights from each other, as discussed above with respect to the semiconductor light emitting device package 100 of FIG. 1), a pyramidal shape (e.g., as discussed above with respect to the semiconductor light emitting device package 200 of FIG. 4), or the like or any combination thereof.

The phosphor layer 650 may be formed on the encapsulation base layer 661. A ratio of a thickness of the phosphor layer 650 to the encapsulation layer 660 may be between 1:2 and 1:4. In one embodiment, the ratio of the thickness of the phosphor layer 650 to the encapsulation layer 660 may be 1:3, or thereabout.

A shape of an upper surface of the phosphor layer 650 may be equal to, or otherwise at least substantially correspond to, a shape of an upper surface of the encapsulation layer 660 having the plurality of patterns 662.

A first electrode 625a electrically connected to a first conductivity-type semiconductor layer 621 may be disposed on the first conductivity-type semiconductor layer 621. A first pad 626a may penetrate through a second conductivity-type semiconductor layer 623 and an active layer 622 to be electrically connected to the first electrode 625a. A first metal post 627a maybe disposed below the first pad 626a and electrically connected thereto.

A second electrode 625b may be disposed below the second conductivity-type semiconductor layer 623 to be electrically connected thereto. The second electrode 625b may be disposed below a portion of the second conductivity-type semiconductor layer 623 to be insulated from the first conductivity-type semiconductor layer 621 and the active layer 622. A second pad 626b may be disposed below the second electrode 625b to be electrically connected thereto. A second metal post 627b may be disposed below the second pad 626b to be electrically connected thereto.

An insulating material layer 624 may be disposed between the electrodes, pads, and metal posts so that the electrodes, pads, and metal posts can be electrically insulated from each other. The insulating material layer 624 may include a first insulation layer 624a, a second insulation layer 624b, and a third insulation layer 624c.

The first insulation layer 624a may be disposed on a side surface of an open portion E (see FIG. 3B) so that the first electrode 625a can be electrically insulated from the active layer 622 and the second conductivity-type semiconductor layer 623. The second insulation layer 624b may be disposed between the first pad 626a and the second pad 626b so that the first pad 626a and the second pad 626b can be electrically insulated from each other. The third insulation layer 624c may be disposed between the first metal post 627a and the second metal post 627b so that the first metal post 627a and the second metal post 627b can be electrically insulated from each other. The third insulation layer 624c may also be disposed on a side surface of a light emitting stack 620.

The lens 690 may be disposed on the phosphor layer 650. Although the lens 690 is illustrated as having a dome-shaped structure, it will be appreciated that the lens 690 may have any other suitable or desired structure. In one embodiment, the shape of the lens 690 may be selected to achieve a suitable or desired beam spread angle of light emitted from the phosphor layer 650. In another embodiment, the lens 690 may protect the phosphor layer 650 from being damaged.

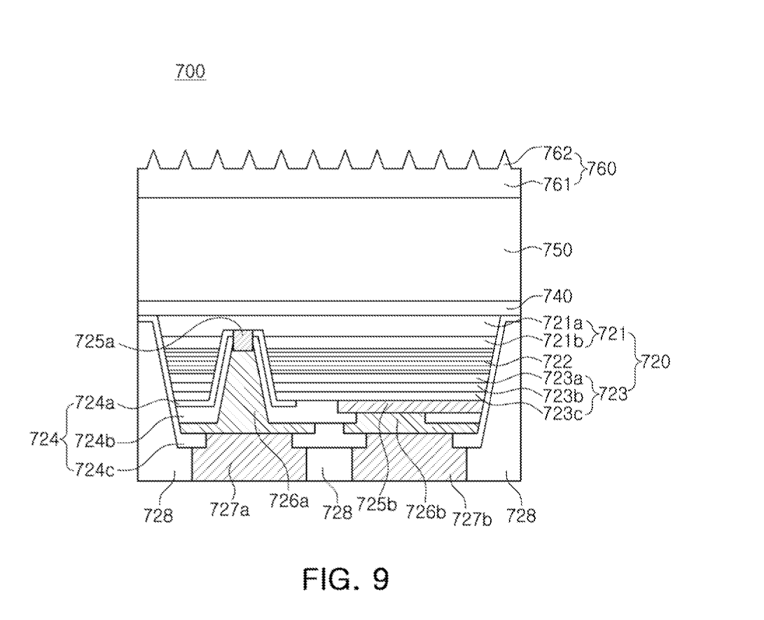

FIG. 9 is a cross-sectional view illustrating a semiconductor light emitting device package according to an example embodiment of the present inventive concept. In FIG. 9, the cross sectional view shown corresponds to the view taken along the line A-A′ of FIG. 1.

Referring to FIG. 9, a semiconductor light emitting device package 700 may have a structure in which a transparent insertion layer 740, a phosphor layer 750, and an encapsulation layer 760 are sequentially stacked on a light emitting stack 720, which includes a first conductivity-type semiconductor layer 721, an active layer 722, and a second conductivity-type semiconductor layer 723. A ratio of a thickness of the encapsulation layer 760 to the phosphor layer 750 may be between 1:2 and 1:4. In one embodiment, the ratio of the thickness of the encapsulation layer 760 to the phosphor layer 750 may be 1:3, or thereabout.

The first conductivity-type semiconductor layer 721 may include a first conductivity-type semiconductor contact layer 721a and a current diffusion layer 721b. An impurity concentration of the first conductivity-type semiconductor contact layer 721a may range from 2×10¹⁸ cm⁻³ to 9×10¹⁹ cm⁻³. A thickness of the first conductivity-type semiconductor contact layer 721a may range from 1 μm to 5 μm. The current diffusion layer 721b may have a structure in which a plurality of layers formed of InₓAl_{y}Ga_{(1-x-y)}N (0≦x, y≦1, 0≦x+y≦1), but having different compositions or different impurity contents, are repeatedly stacked. For example, the current diffusion layer 721b may be an N-type superlattice layer in which a plurality of layers including an N-type GaN layer and/or an AlₓIn_{y}Ga_{z}N (0≦x,y,z≦1, x+y+z≠0) layer, each having a thickness ranging from 1 nm to 500 nm and having different compositions, are repeatedly stacked. An impurity concentration of the current diffusion layer 721b may range from 2×10¹⁸ cm⁻³ to 9×10¹⁹ cm⁻³. If necessary, an insulating material layer may be added to the current diffusion layer 721b.

The second conductivity-type semiconductor layer 723 may include an electron-blocking layer (EBL) 723a, a low-concentration P-type GaN layer 723b, and a high-concentration P-type GaN layer 723c provided as a contact layer. For example, the electron-blocking layer 723a may have a structure in which a plurality of InₓAl_{y}Ga_{(1-x-y)}N (0≦x≦1, 0≦y≦1, 0≦x+y≦1) layers, each having a thickness between 5 nm to 100 nm and having different compositions, are stacked. In another example, the electron-blocking layer 723a may have a single-layer structure formed of Al_{y}Ga_{(1-y)}N (0<y≦1). In one embodiment, the electron-blocking layer 723a may be configured such that, an energy band gap of the electron-blocking layer 723a decreases with increasing distance from the active layer 722 increases.

An upper surface of the encapsulation layer 760 may be textured. The encapsulation layer 760 may include an encapsulation base layer 761 and a plurality of patterns 762 disposed on the encapsulation base layer 761. The plurality of patterns 762 may have a conical shape (e.g., having equal diameters and heights or different diameters and heights from each other, as discussed above with respect to the semiconductor light emitting device package 100 of FIG. 1), a pyramidal shape (e.g., as discussed above with respect to the semiconductor light emitting device package 200 of FIG. 4), or the like or any combination thereof.

A first electrode 725a electrically connected to a first conductivity-type semiconductor layer 721 may be disposed on the first conductivity-type semiconductor layer 721. A first pad 726a may penetrate through a second conductivity-type semiconductor layer 723 and an active layer 722 to be electrically connected to the first electrode 725a. A first metal post 727a maybe disposed below the first pad 726a and electrically connected thereto.

A second electrode 725b may be disposed below the second conductivity-type semiconductor layer 723 to be electrically connected to the second conductivity-type semiconductor layer 723. The second electrode 725b may be disposed below a portion of the second conductivity-type semiconductor layer 723 to be insulated from the first conductivity-type semiconductor layer 721 and the active layer 722. A second pad 726b may be disposed below the second electrode 725b to be electrically connected thereto. A second metal post 727b may be disposed below the second pad 726b to be electrically connected thereto.

An insulating material layer 724 may be disposed between the electrodes, pads, and metal posts so that the electrodes, pads, and metal posts can be electrically insulated from each other. The insulating material layer 724 may include a first insulation layer 724a, a second insulation layer 724b, and a third insulation layer 724c.

The first insulation layer 724a may be disposed on a side surface of an open portion E (see FIG. 3B) so that the first electrode 725a can be electrically insulated from the active layer 722 and the second conductivity-type semiconductor layer 723. The second insulation layer 724b may be disposed between the first pad 726a and the second pad 726b so that the first pad 726a and the second pad 726b can be electrically insulated from each other. The third insulation layer 724c may be disposed between the first metal post 727a and the second metal post 727b so that the first metal post 727a and the second metal post 727b can be electrically insulated from each other. The third insulation layer 724c may also be disposed on a side surface of a light emitting stack 720.

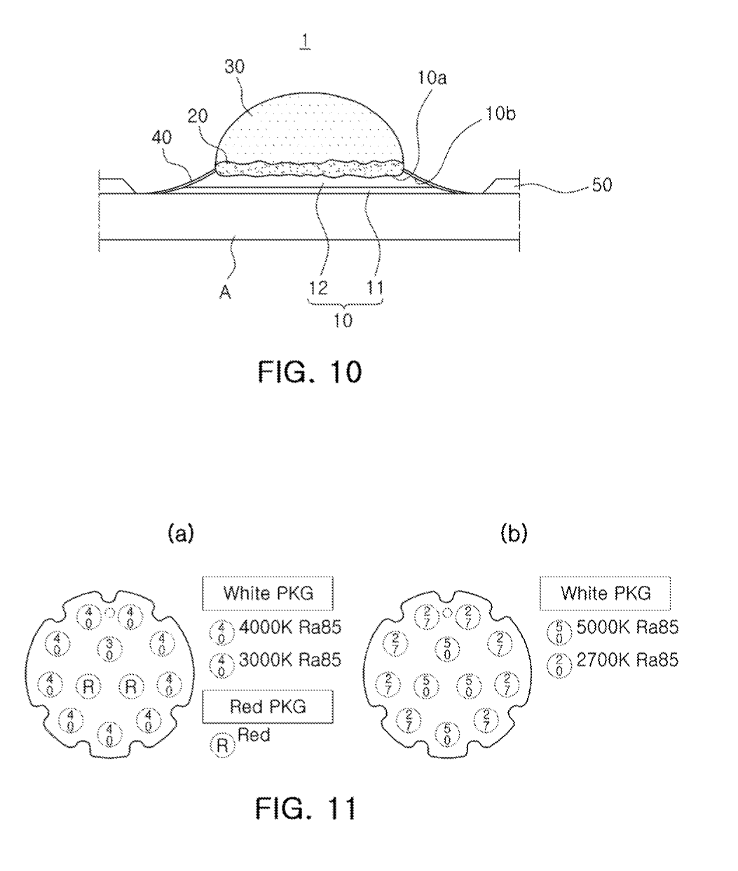

FIG. 10 is a cross-sectional view illustrating an interconnected bump, which may be included in a semiconductor light emitting device package, according to an example embodiment of the present inventive concept. In the discussion below, the interconnected bump is described as being formed below the first metal post 127a and the second metal post 127b of FIG. 1. It will be appreciated, however, that the interconnected bump may likewise be formed below the first metal post and the second metal post of any of the semiconductor light emitting device package discussed above with respect to FIGS. 4 to 9.

Referring to FIG. 10, an under bump metallurgy (UBM) layer 10 may improve the bonding power of the interface between an electrode A of a semiconductor light emitting device and a solder bump 30 and provide an electrical pathway. As exemplarily illustrated, the electrode A of the semiconductor light emitting device may be provided as the first metal post 127a and the second metal post 127b. In addition, the UBM layer 10 may prevent solder from permeating into an electrode during a reflow process. For example, the UBM layer 10 may prevent a constituent of the solder from permeating into the electrode A.

The UBM layer 10 may be disposed on a surface of the electrode A and may include a first surface 10a disposed to be in contact with an intermetallic compound (IMC) 20 on an upper surface of the electrode A and a second surface 10b extended from an edge of the first surface 10a to be connected to the electrode A.

The first surface 10a may have an entirely flat structure and may define an upper surface of the UBM layer 10. The second surface 10b may have a structure gently tilted towards the electrode A from the first surface 10a and may define a side surface of the UBM layer 10.

The UBM layer 10 may be formed of a metal to be electrically connected to the electrode A. In one embodiment, the UBM layer 10 may have a multilayer-film structure. For example, the UBM layer 10 may include a first layer 11 (e.g., formed of chromium (Cr), titanium (Ti), etc.) and a second layer 12 (e.g., formed of nickel (Ni), copper (Cu), etc.) disposed on the first layer 11). In another embodiment, the UBM layer 10 may have a single-layer structure (e.g., formed of a single layer of nickel (Ni), copper (Cu), etc.). The UBM layer 10 may be formed using a process such as sputtering, e-beam depositing, and plating.

The IMC 20 may be formed on the first surface 10a of the UBM layer 10. The IMC 20 may be formed during a reflow process in which the solder bump 30 is formed. The IMC 20 may be formed when a material in the solder (e.g., tin (Sn)) reacts to a metal (e.g., nickel (Ni)) in the UBM layer 10, thereby forming a

pseudo-binary alloy of (e.g., a Sn—Ni alloy). The solder bump 30 may be bonded to the UBM layer 10, with the IMC 20 serving as a medium. For example, the solder bump 30 may be strongly bonded to an upper surface of the UBM layer 10, by the IMC 20 serving as a contact agent. The solder bump 30 maybe formed by reflowing the solder on the UBM layer 10. For the solder, for example, SAC30b (Sn_{96.5}Ag_{3.0}Cu_{0.5}) may be used.

The barrier layer 40 may be formed to cover the second surface 10b of the UBM layer 10. The IMC 20 and the solder bump 30 may be prevented from being diffused on the second surface 10b of the UBM layer 10 by significantly reducing wettability of the barrier layer 40 against the solder bump 30. This may be implemented by forming the barrier layer 40 to have significantly low wettability against the IMC 20 and the solder bump 30.

The barrier layer 40 may be provided as an oxide film containing at least one element of the UBM layer 10. For example, the barrier layer 40 may be an oxide film containing nickel (Ni), copper (Cu), etc. The barrier layer 40 may be formed by oxidizing the second surface 10b of the UBM layer 10. For example, the barrier layer 40 may be formed by oxidizing the second surface 10b of the UBM layer 10 during a thermal oxidation process, a plasma oxidation process, or the like.

A passivation layer 50 may be disposed around the UBM layer 10 on the electrode A. The passivation layer 50 may be formed of, for example, SiO₂.

The passivation layer 50 may be spaced apart from the UBM layer 10 on the electrode A by a predetermined distance so as not to come into contact with the UBM layer 10. The passivation layer 50 may have a thin-film structure, and have a height that is lower than a height of the UBM layer 10. In detail, the first surface 10a of the UBM layer 10 may be disposed in a position higher than an upper surface of the passivation layer 50, as measured from the surface of the electrode A.

As exemplarily illustrated, the passivation layer 50 has been exemplified as being disposed around the UBM layer 10, but is not limited thereto. The passivation layer 50 may be disposed in a selective manner. Such a bump structure may be applied to other packages illustrated above.

FIG. 11 schematically illustrates a white light source module employing a semiconductor light emitting device package, according to an example embodiment of the present inventive concept.

Referring to FIG. 11, each of the light source modules may include a plurality of light emitting device packages mounted on a circuit substrate thereof. Generally, the light emitting device packages may be provided as discussed above with respect to any of FIGS. 1 to 10. It will be appreciated, however, that a light source module may include one or more light emitting device packages that are not provided as discussed herein.

In the illustrated embodiment, the plurality of light emitting device packages included in a single light source module may be configured to generate different wavelengths of light. In another embodiment, however, the plurality of light emitting device packages included in a single light source module may be configured to generate identical wavelengths of light.

The white light source module (a) shown in FIG. 11 may include white light emitting device packages configured to emit light having color temperatures in a range from 4000K to 3000K, and red light emitting device packages. The color temperature of the white light source module may be adjusted to be between 3000K and 4000K, and the white light source module (a) may provide white light having a color rendering index Ra of 85 to 100.

The white light source module (b) shown in FIG. 11 may only include white light emitting device packages, some of which configured to emit white light having different color temperatures. For example, the color temperature of the white light source module (b) may be adjusted to be between 2700K and 5000K by configuring the white light source module of white light emitting device packages having a color temperature of 2700K and white light emitting device packages having a color temperature of 5000K, and the white light source module (b) may provide white light having a color rendering index Ra of 85 to 99. The numbers of the white light emitting device packages having a color temperature of 2700K and the white light emitting device packages having a color temperature of 5000K may be adjusted depending on the color temperature setup values thereof. For example, in the case of a lighting device having a color temperature setup value of about 4000K, the number of the light emitting device packages having a color temperature of 4000K may be higher than the number of the light emitting device packages having a color temperature of 3000K or the red light emitting device packages.

In one embodiment, a white light emitting device may be formed by adding a yellow, green, red, or orange phosphor to a light emitting device having a light emitting stack configured to emit blue light. In another embodiment, a white light emitting device may be formed by mixing at least one of purple, blue, green red, and infrared light emitted from one or more light emitting devices (e.g., such that the color temperature and color rendering index (CRI) of the resultant white light may be adjusted).

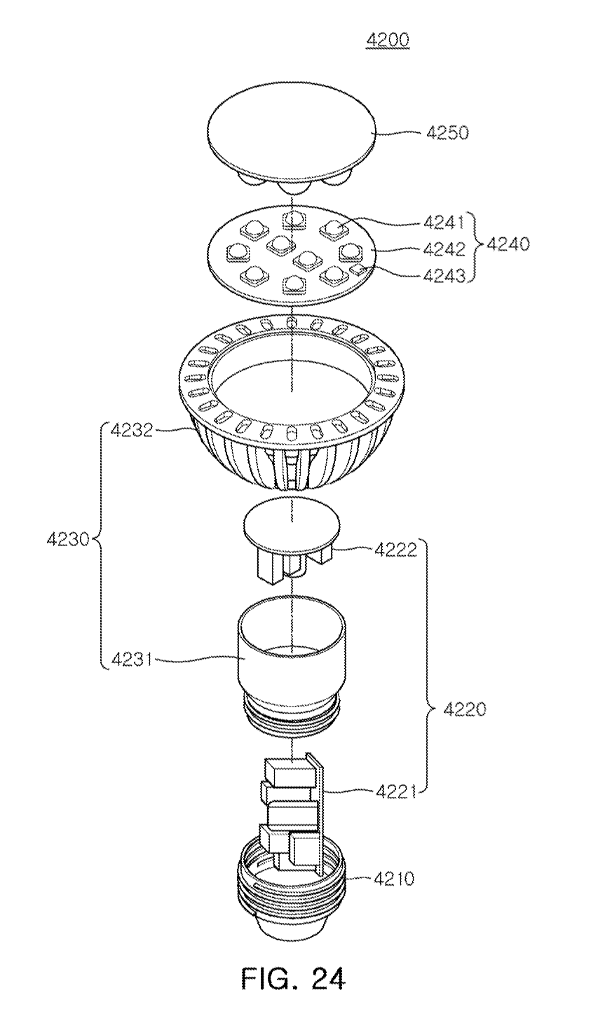

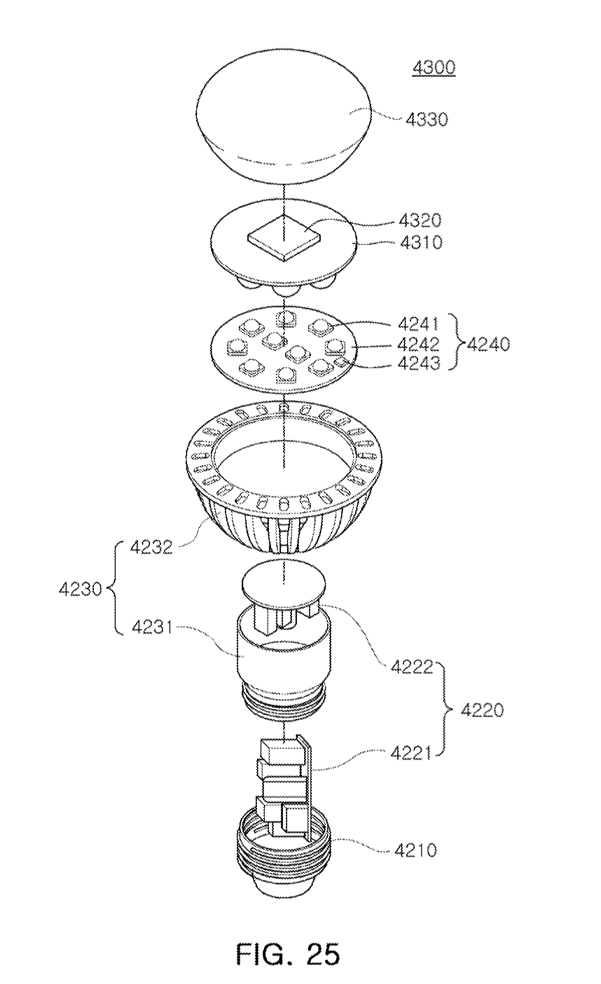

Any of the white light source modules described above may be used as a light source module 4240 of a bulb-type lighting device (see 4200 of FIG. 24 or 4300 of FIG. 25).

In a case in which a white light source module comprises identical light emitting device packages, the color of light may be determined according to the wavelength of an LED chip, a light emitting device, and type and mixing ratio of phosphors within the LED chip or light emitting device. In a case in which the LED chip emits white light, the color temperature and color rendering index thereof may be adjusted.

For example, in a case in which the LED chip emits blue light, a light emitting device package including at least one of yellow, green, and red phosphors may be adjusted to emit white light having a variety of color temperatures depending on mixing ratios of the phosphors. On the other hand, in a case in which a green or red phosphor is applied to a blue LED chip, a light emitting device package thereof may be adjusted to emit green light or red light. As described above, the color temperature and the color rendering index of white light may be adjusted by mixing a white light emitting device package with a green or red light emitting device package. In addition, the white light source module may be configured to include at least one light emitting device emitting purple, blue, green, red, or infrared light.

In this case, the color rendering index of light capable of being emitted by the lighting device may be adjusted from a level of light emitted by a sodium lamp to a level of sunlight, and the lighting device may generate white light having a wide range of color temperatures between 1,500K and 20,000K. If necessary, the lighting device may adjust the color of light by generating purple, blue, green, red, or orange visible light, or infrared light as desired. In addition, light having a special wavelength able to promote plant growth may be generated thereby.

FIG. 12 illustrates a CIE 1931 color space chromaticity diagram provided to describe a wavelength conversion material which may be applied to a semiconductor light emitting device package according to an example embodiment of the present inventive concept.

Referring to FIG. 12, white light formed by a mixture of a UV LED or a blue LED with yellow, green, and red phosphors and/or green and red LEDs may have two or more peak wavelengths and may be positioned on a line segment of the CIE 1931 color space chromaticity diagram connecting (x and y) coordinates of (0.4476, 0.4074), (0.3484, 0.3516), (0.3101, 0.3162), (0.3128, 0.3292), and (0.3333, 0.3333). The white light may be positioned in a region surrounded by the line segment and a black body radiation spectrum. The color temperature of the white light may be between 2,000K and 20,000K.

A variety of materials such as a phosphor and/or a quantum dot may be used as a material to convert the wavelength of light emitted from a semiconductor light emitting device. The phosphor may have an empirical formula and a color as follows:

Oxide-based phosphor: yellow and green Y₃Al₅O₁₂:Ce, Tb₃Al₅O₁₂:Ce, and Lu₃Al₅O₁₂:Ce

Silicate-based phosphor: yellow and green (Ba,Sr)₂SiO₄:Eu, and yellow and orange (Ba,Sr)₃SiO₅:Ce

Nitride-based phosphor: green β-SiAlON:Eu, yellow La₃Si₆N₁₁:Ce, orange α-SiAlON:Eu, and red CaAlSiN₃:Eu, Sr₂Si₅N₈:Eu, SrSiAl₄N₇:Eu, SrLiAl₃N₄:Eu, and Ln₄₋ₓ(Eu_{z}M_{1-z})ₓSi_{12-y}Al_{y}O_{3+x+y}N_{18-x-y} (0.5≦x≦3, 0<z<0.3, 0<y≦4)—formula 1

In formula 1, Ln may be at least an element selected from a group consisting of a IIIa-based element and a rare-earth element, and M may be at least one element selected from a group consisting of Ca, Ba, Sr, and Mg.

Fluoride-based phosphor: KSF-based red K₂SiF₆:Mn₄⁺, K₂TiF₆:Mn₄⁺, NaYF₄:Mn₄⁺, and NaGdF₄:Mn₄⁺ (For example, a composition ratio of the Mn may be 0<z≦0.17).

In one embodiment, the phosphor is a stoichiometric compound, and each element thereof may be replaced with another element of the same group on the periodic table. For example, Sr may be replaced with an alkaline earth element (group 2) such as Ba, Ca, Mg, and the like, and Y may be replaced with a lanthanum-based element such as Tb, Lu, Sc, Gd, and the like. In addition, an activator Eu and the like may be replaced with Ce, Tb, Pr, Er, Yb, or the like, according to a desired energy level. A single activator may be used, or a sub-activator may be additionally applied thereto for a transformation of characteristics.

In one embodiment, fluoride-based red phosphors may be coated with a fluoride material not containing Mn, or may further include organic material coated on a surface of the phosphor or a surface of the fluoride coating not containing Mn, for improvements in the reliability thereof in high temperature and high humidity environments. Such a fluoride-based red phosphor may be applied to a high-resolution TV such as an ultra-high-definition (UHD) TV, unlike other phosphors, since narrow FWHM of 40 nm or less may be implemented.

Table 2 below provides the types of phosphors categorized by use of white light emitting devices having a blue LED chip (440 to 460 nm) or a UV LED chip (380 to 440 nm).

TABLE 2

| Use | Phosphor |
|---|---|
| LED TV BLU | β-SiAlON:Eu²⁺, (Ca, Sr)AlSiN₃:Eu²⁺, |
| | La₃Si₆N₁₁:Ce³⁺, K₂SiF₆:Mn⁴⁺, SrLiAl₃N₄:Eu, |
| | Ln₄₋ₓ(Eu_{z}M_{1-z})ₓSi_{12-y}Al_{y}O_{3+x+y}N_{18-x-y}(0.5 ≦ x ≦ 3, |
| | 0 < z < 0.3, 0 < y ≦ 4), K₂TiF₆:Mn⁴⁺, NaYF₄:Mn⁴⁺, |
| | NaGdF₄:Mn⁴⁺ |
| Lighting Device | Lu₃Al₅O₁₂:Ce³⁺, Ca-α-SiAlON:Eu²⁺, |
| | La₃Si₆N₁₁:Ce³⁺, (Ca, Sr)AlSiN₃:Eu²⁺, |
| | Y₃Al₅O₁₂:Ce³⁺, K₂SiF₆:Mn⁴⁺, SrLiAl₃N₄:Eu, |
| | Ln₄₋ₓ(Eu_{z}M_{1-z})ₓSi_{12-y}Al_{y}O_{3+x+y}N_{18-x-y}(0.5 ≦ x ≦ 3, |
| | 0 < z < 0.3, 0 < y ≦ 4), K₂TiF₆:Mn⁴⁺, NaYF₄:Mn⁴⁺, |
| | NaGdF₄:Mn⁴⁺ |
| Side Viewing | Lu₃Al₅O₁₂:Ce³⁺, Ca-α-SiAlON:Eu²⁺, |
| (Mobile | La₃Si₆N₁₁:Ce³⁺, (Ca, Sr)AlSiN₃:Eu²⁺, |
| Terminal, | Y₃Al₅O₁₂:Ce³⁺, (Sr, Ba, Ca, Mg)₂SiO₄:Eu²⁺, |
| Notebook PC) | K₂SiF₆:Mn⁴⁺, SrLiAl₃N₄:Eu, |
| | Ln₄₋ₓ(Eu_{z}M_{1-z})ₓSi_{12-y}Al_{y}O_{3+x+y}N_{18-x-y}(0.5 ≦ x ≦ 3, |
| | 0 < z < 0.3, 0 < y ≦ 4), K₂TiF₆:Mn⁴⁺, NaYF₄:Mn⁴⁺, |
| | NaGdF₄:Mn⁴⁺ |
| Electronic | Lu₃Al₅O₁₂:Ce³⁺, Ca-α-SiAlON:Eu²⁺, |
| Component For | La₃Si₆N₁₁:Ce³⁺, (Ca, Sr)AlSiN₃:Eu²⁺, |
| Automobile | Y₃Al₅O₁₂:Ce³⁺, K₂SiF₆:Mn⁴⁺, SrLiAl₃N₄:Eu, |
| (Headlamp, etc.) | Ln₄₋ₓ(Eu_{z}M_{1-z})ₓSi_{12-y}Al_{y}O_{3+x+y}N_{18-x-y}(0.5 ≦ x ≦ 3, |
| | 0 < z < 0.3, 0 < y ≦ 4), K₂TiF₆:Mn⁴⁺, NaYF₄:Mn⁴⁺, |
| | NaGdF₄:Mn⁴⁺ |

In one embodiment, a material containing quantum dots may be used instead of (or may be combined with) the phosphor. Materials containing quantum dots or phosphors can also be generically referred to as “wavelength conversion material.”

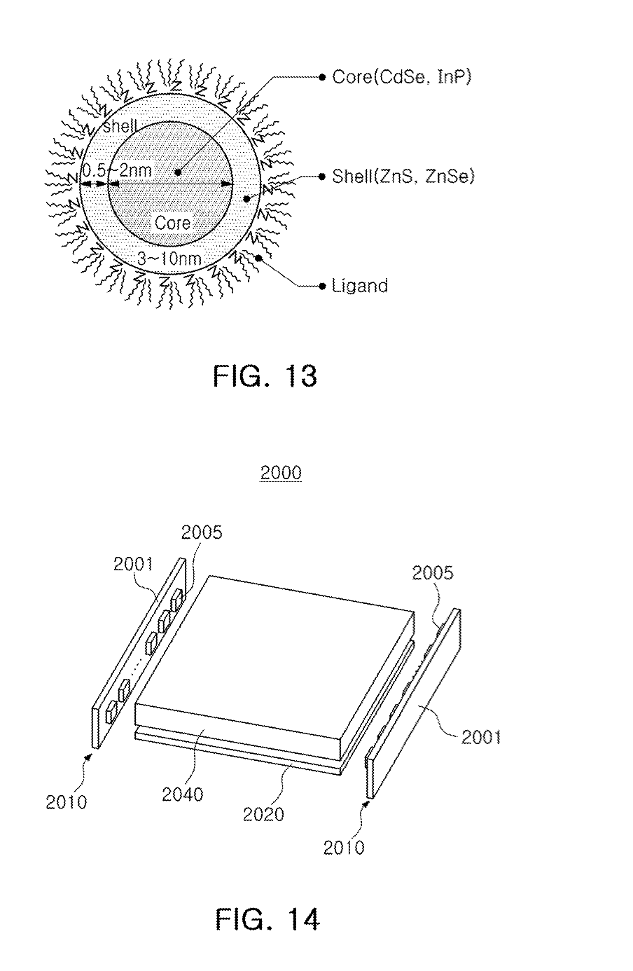

FIG. 13 is a view schematically illustrating a cross section of a quantum dot.

Referring to FIG. 13, a quantum dot (QD) may have a core-shell structure formed of a II-VI-based compound semiconductor or a III-V-based compound semiconductor. For example, the quantum dot may have a core such as CdSe, InP, and the like, and a shell such as ZnS and ZnSe. In addition, the quantum dot may include a ligand to ensure a stable core and shell. For example, a diameter of the core may range from 1 nm to 30 nm (e.g., in a range from 3 nm to 10 nm). A thickness of the shell may range from 0.1 nm to 20 nm (e.g., in a range from 0.5 nm to 2 nm).

The use of quantum dots may allow a range of colors to be implemented, depending on the size thereof, and, in particular, when quantum dots are used as an alternative to phosphor, quantum dots may be used as a replacement for red or green phosphors. When quantum dots are used, a narrow full width at half maximum (FWHM) of, for example, about 35 nm, may be implemented.

Wavelength conversion material may be contained in an encapsulant to be formed, or may be produced in advance (e.g., in the form of a film) and attached to a surface of an optical structure such as an LED chip or a light guide. In the latter case, the wavelength conversion material having a constant thickness may be easily applied to a desired region.

FIG. 14 is a perspective view schematically illustrating a backlight unit employing a semiconductor light emitting device package, according to an example embodiment of the present inventive concept.

Referring to FIG. 14, a backlight unit 2000 may include a light guide panel 2040 and light source modules 2010 provided in both sides of the light guide panel 2040. In addition, the backlight unit 2000 may further include a reflection board 2020 disposed below the light guide panel 2040. The backlight unit 2000 may be provided as an edge-type backlight unit.

As exemplarily illustrated, the light source module 2010 may only be provided in one side of the light guide panel 2040, or may be provided in the other side as well as in both sides of the light guide panel 2040. The light source module 2010 may include a printed circuit board 2001 and a plurality of light sources 2005 mounted on an upper surface of the printed circuit board 2001. In one embodiment, at least one of the light sources 2005 may be provided as any light source module discussed above with respect to FIG. 11, or may otherwise include one or more semiconductor light emitting device packages as exemplarily described herein.

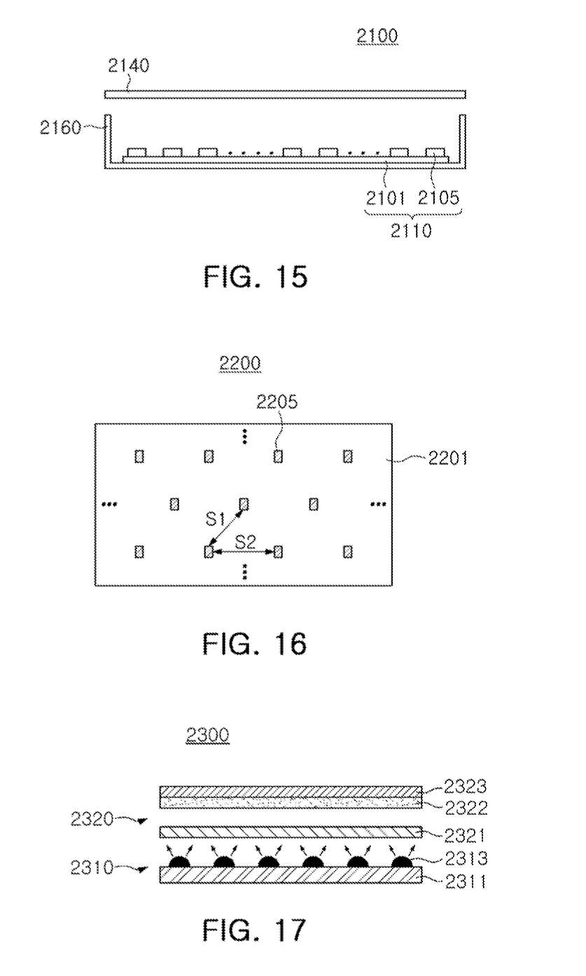

FIG. 15 is a view illustrating a direct-type backlight unit according to an example embodiment of the present inventive concept.

Referring to FIG. 15, a backlight unit 2100 may include a light diffusion panel 2140 and light source modules 2110 arranged below the light diffusion panel 2140. In addition, the backlight unit 2100 may further include a bottom case 2160 disposed below the light diffusion panel 2140 and having the light source modules 2110. The backlight unit 2100 may be provided as a direct-type backlight unit.

The light source modules 2110 may include a printed circuit board 2101 and a plurality of light sources 2105 mounted on an upper surface of the printed circuit board 2101. In one embodiment, at least one of the light sources 2105 may be provided as any light source module discussed above with respect to FIG. 11, or may otherwise include one or more semiconductor light emitting device packages as exemplarily described herein.

FIG. 16 is a plan view illustrating an arrangement of light sources of a direct-type backlight unit employing a semiconductor light emitting device package, according to another example embodiment of the present inventive concept.

Referring to FIG. 16, a direct-type backlight unit 2200 maybe configured to have a plurality of light sources 2205 arranged on a substrate 2201. In one embodiment, at least one of the light sources 2205 may be provided as any light source module discussed above with respect to FIG. 11, or may otherwise include one or more semiconductor light emitting device packages as exemplarily described herein.

The light sources 2205 may be arranged in a row-and-column matrix structure, in which rows and columns form a zigzag pattern. For example, inside a first matrix in which the plurality of light sources 2205 are arranged in rows and columns not forming a zigzag pattern, a second matrix having a shape equal to a shape of the first matrix is disposed. In such an example arrangement, a light source 2205 of the second matrix is disposed inside a rectangle formed of four adjacent light sources 2205 included in the first matrix. By arranging the light sources in rows and columns forming a zigzag pattern rather than in straight rows and columns, the number of light sources 2205 may be reduced by 15% to 25% per equal light emitting area.

In the illustrated direct-type backlight unit, the arrangement of light sources 2205 of the first matrix and distances therebetween may be adjusted to be different from the arrangement of light sources 2205 of the second matrix and distances therebetween, to obtain a uniform degree of brightness and improved light efficiency, if necessary.

Aside from the method of arranging the plurality of light sources 2205 detailed above, a method of adjusting distances S1 and S2 between two adjacent light sources may be used to obtain a uniform degree of brightness.

FIG. 17 is a cross-sectional view illustrating a direct-type backlight unit employing a semiconductor light emitting device package, according to an example embodiment of the present inventive concept.

Referring to FIG. 17, a backlight unit 2300 may include an optical sheet 2320 and a light source module 2310 arranged below the optical sheet 2320.

The optical sheet 2320 may include a diffusion sheet 2321, a light collection sheet 2322, a protection sheet 2323, and the like.

The light source module 2310 may include a circuit board 2311 and an optical device 2313 mounted on the circuit board 2311. The optical device 2313 may include a plurality of light sources and an optical member disposed on the plurality of light sources.

The plurality of light sources may be provided as white light source modules of FIG. 1 and FIGS. 4 to 9.

The optical member may adjust beam spread angle of light through refraction. A beam-spread-angle lens diffusing light from a light source to a relatively large area may be mainly used. A light source to which such an optical member has been attached may have a relatively wide light distribution. Thus, the number of light sources required for an equal area may be reduced by using such a light source module for a backlight, a flat plate light, and the like.

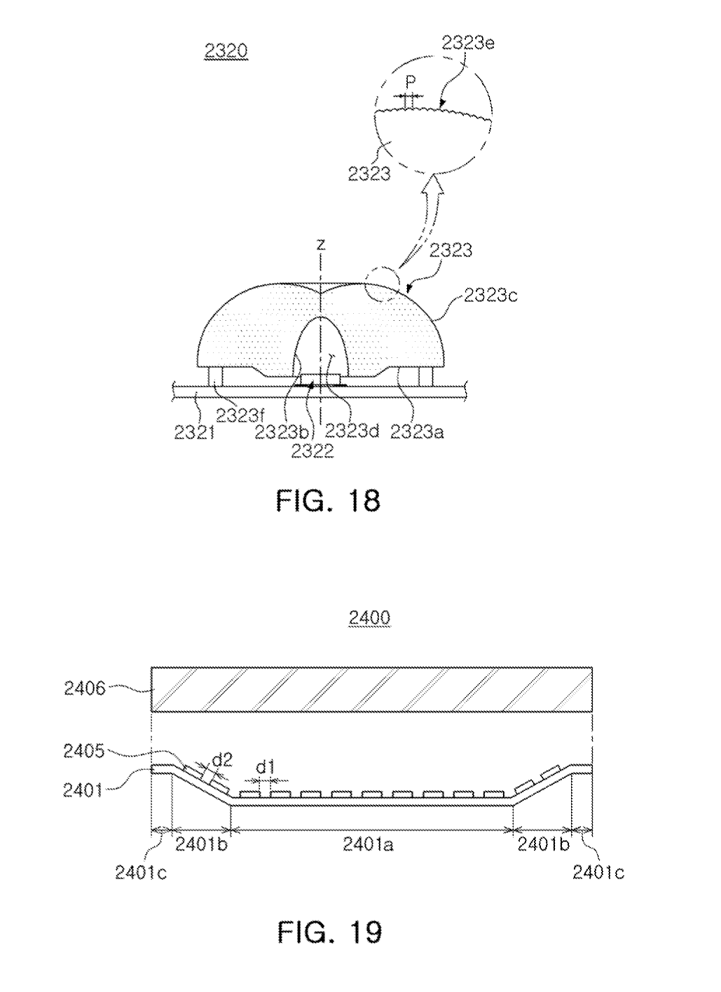

FIG. 18 is an optical device 2320 employing a light emitting device package, according to an example embodiment of the present inventive concept.

Referring to FIG. 18, the optical device 2320 may include a light source 2322 and an optical member 2323 disposed above the light source 2322. In one embodiment, at least one of the light sources 2322 may be provided as any light source module discussed above with respect to FIG. 11, or may otherwise include one or more semiconductor light emitting device packages as exemplarily described herein. The optical device 2320 may be employed as the optical device 2313 of FIG. 17.

The optical member 2323 may include a bottom surface 2323a disposed above the light source 2322, a light entry surface 2323b on which light from the light source 2322 is incident, and a light exit surface 2323c through which the light is emitted.

The bottom surface 2323a may have a hollow 2323d indented therein in a direction of the light exit surface 2323c, in a center thereof through which an optical axis Z of the light source 2322 passes. A surface of the hollow 2323d may be defined as the light entry surface 2323b on which the light of the light source 2322 may be incident. In other words, the light entry surface 2323b may form the surface of the hollow 2323d.

A central portion of the bottom surface 2323a, connected to the light entry surface 2323b, may partially protrude in a direction of the light source 2322, to form a non-flat-plate structure. For example, the bottom surface 2323a may partially protrude along an edge portion of the hollow 2323d and, thus, the bottom surface 2323a may have a non-flat-plate structure, not a flat plate structure. A plurality of supports 2323f may be disposed on the bottom surface 2323a to fix and support the optical device 2323 when the optical device 2323 is installed on a circuit board 2321.

The light exit surface 2323c may protrude in a dome shape in an upper direction (or a light exit direction) of an edge of the bottom surface 2323a on which the light exit surface 2323c may be connected to the bottom surface 2323a. In addition, the light exit surface 2323c may have a structure in which a central portion thereof through which the optical axis Z passes may be hollowed in a direction of the hollow 2323d.

On the light exit surface 2323c, a plurality of concave-convex portions 2323e may be arranged regularly in a direction of the edge on which the light exit surface 2323c is connected to the bottom surface 2323a from the optical axis (i.e., the Z-axis). The plurality of concave-convex portions 2323e may have ring shapes, corresponding to a horizontal cross section of the optical device 2322, and form concentric circles based on the optical axis (i.e., the Z-axis). The plurality of concave-convex portions 2323e may be arranged on a surface of the light exit surface 2323c, forming a regular pattern spread in a radial shape.

The plurality of concave-convex portions 2323e may be spaced apart from each other at a regular pitch P to form a pattern. In this case, the pitch P between the plurality of concave-convex portions 2323e may range from 0.01 mm to 0.04 mm. The plurality of concave-convex portions 2323e may serve to offset the difference in performances of optical members occurring due to a small process error during a manufacturing process thereof, thereby improving uniformity in light distribution.

FIG. 19 is a cross-sectional view illustrating a direct-type backlight unit employing a semiconductor light emitting device package, according to another example embodiment of the present inventive concept.

Referring to FIG. 19, in a backlight unit 2400, light sources 2405 may be mounted on a circuit board 2401, and at least one optical sheet 2406 maybe disposed above the light sources 2405.

The light sources 2405 may be white light emitting devices containing a red phosphor, and a module in which the light sources 2405 are mounted on the circuit board 2401 may be light source modules of FIG. 15 and FIG. 16.

The circuit board 2401 may include a first planar portion 2401a, which corresponds to a main portion of the circuit board 2401, an inclined portion 2401b disposed around the first planar portion 2401a, which corresponds to a bent portion of the circuit board 2401, and a second planar portion 2401c disposed in a corner of the circuit board 2401, disposed outwardly from the inclined portion 2401b. The light sources 2405 may be arranged on the first planar portion 2401a at an interval of a first distance dl, and one or more light sources 2405 may be arranged on the inclined portion 2401b at an interval of a second distance d2. The first distance dl may be equal to the second distance d2. A width of the inclined portion 2401b (or a length in a cross section thereof) may be smaller than a width of the first planar portion 2401a and greater than a width of the second planar portion 2401c. If necessary, at least one light source 2405 may be arranged on the second planar portion 2401c.

An inclination of the inclined portion 2401b may be higher than 0° and lower than 90°, as measured from the surface of the first planar portion 2401a. The circuit board 2401 may have the above-mentioned structure, such that the level of brightness of light may be uniformly maintained, even in a corner of the optical sheet 2406.

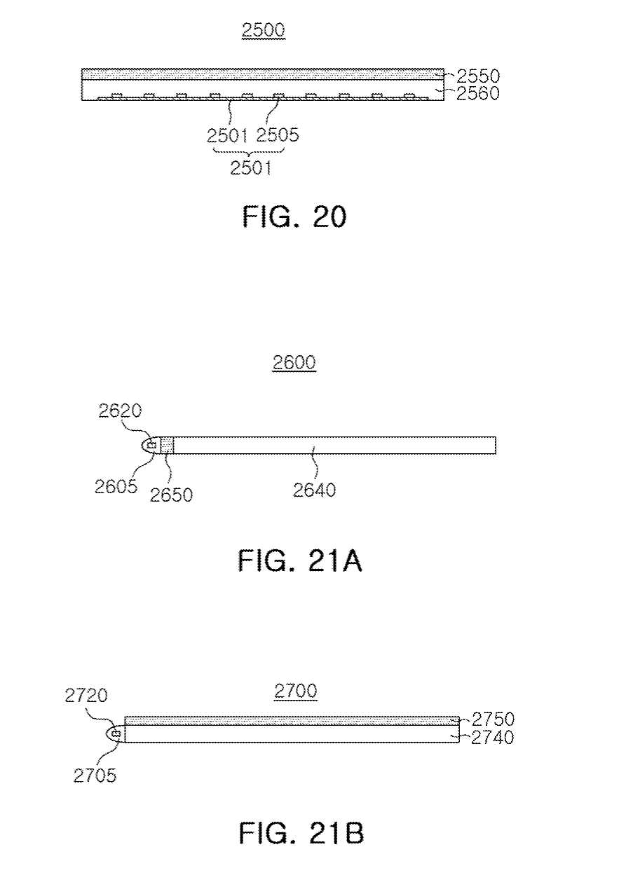

FIGS. 20, 21A, and 21B are cross-sectional views schematically illustrating backlight units employing a semiconductor light emitting device, according to other example embodiments of the present inventive concept. In backlight units 2500, 2600, and 2700 of FIGS. 20, 21A, and 21B, respectively, wavelength conversion units 2550, 2650, and 2750 may not be disposed internally of light sources 2505, 2605, and 2705. Rather, the wavelength conversion units 2550, 2650, and 2750 are external to the light sources 2505, 2605, and 2705, and internally of backlight units 2500, 2600, and 2700 in order to convert the wavelength of light. In one embodiment, any of the light sources 2505, 2605, and 2705 may be provided as any of the light sources discussed above with respect to FIG. 11, or any of light sources 2405, or may otherwise include one or more semiconductor light emitting device packages as exemplarily described herein. It will nevertheless be appreciated that any of the light sources 2505, 2605, and 2705 may be provided in a manner not discussed above.

Referring to FIG. 20, the backlight unit 2500 may be provided as a direct-type backlight unit including a wavelength conversion unit 2550, light source modules 2510 arranged below the wavelength conversion unit 2550, and a bottom case 2560 accommodating the light source modules 2510. In addition, the light source modules 2510 may include a printed circuit board 2501 and a plurality of light sources 2505 mounted on the printed circuit board 2501.

In the backlight unit 2500, the wavelength conversion unit 2550 maybe disposed on the bottom case 2560. Thus, a wavelength of at least a portion of light emitted by the light source modules 2510 may be converted by the wavelength conversion unit 2550. The wavelength conversion unit 2550 may be manufactured as a separate film to be applied, but may also be integrally united with a light diffusion panel (not illustrated).

Referring to FIGS. 21A and 21B, the backlight units 2600 and 2700 may be provided as edge-type backlight units including wavelength conversion units 2650 and 2750, light guide panels 2640 and 2740, and reflective units 2620 and 2720 and light sources 2605 and 2705 disposed on aside of the light guide panels 2640 and 2740.

Light emitted by the light sources 2605 and 2705 may be directed to the inside of the light guide panels 2640 and 2740 by the reflective units 2620 and 2720. In the backlight unit 2600 of FIG. 21A, the wavelength conversion unit 2650 may be disposed between the light guide panel 2640 and the light source 2605. In the backlight unit 2700 of FIG. 21B, the wavelength conversion unit 2750 may be disposed on a light emission surface of the light guide panel 2740.

Generally, a phosphor material may be included in the wavelength conversion units 2550, 2650, and 2750 of FIGS. 20, 21A, and 21B. In one embodiment, a phosphor may be used to supplement a weakness associated with quantum dot material (i.e., a lack of significant resistance to heat from a light source or moisture). Wavelength conversion units 2550, 2650, and 2750 in FIGS. 20, 21A, and 21B may be applied to the backlight units 2500, 2600, and 2700.

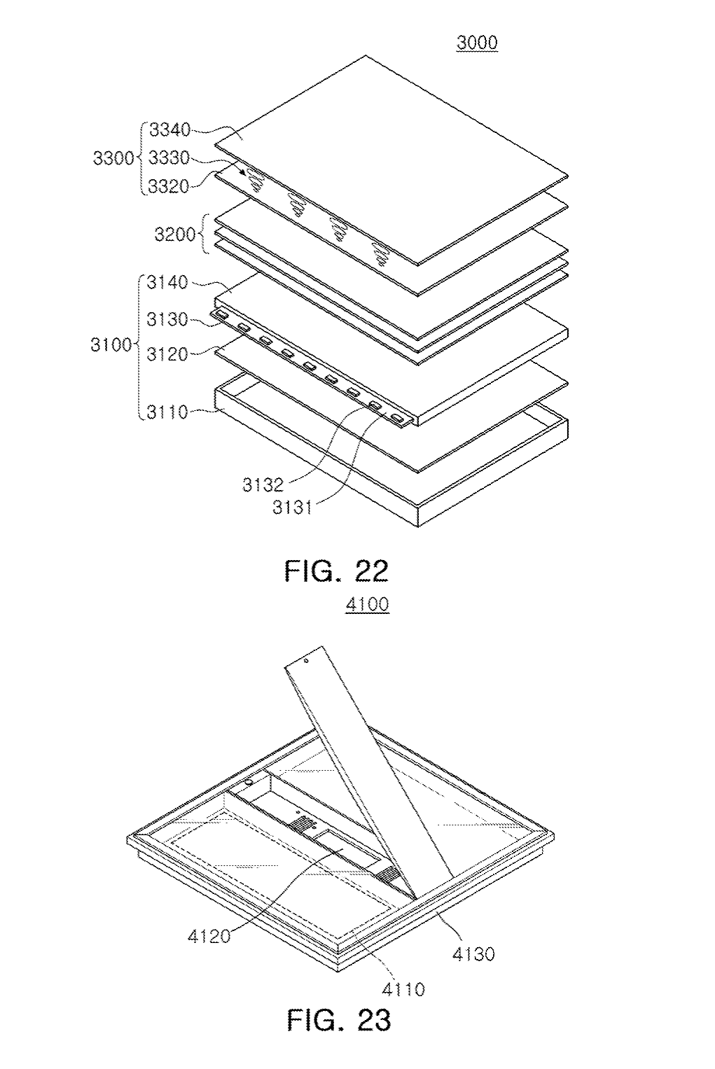

FIG. 22 is an exploded perspective view illustrating a display device employing a semiconductor light emitting device package, according to an example embodiment of the present inventive concept.

Referring to FIG. 22, a display device 3000 may include a backlight unit 3100, an optical sheet 3200, and an image display panel 3300 such as a liquid crystal panel.

The backlight unit 3100 may include a bottom case 3110, a reflective board 3120, a light guide panel 3140, and a light source module 3130 provided in at least a side of the light guide panel 3140. The light source module 3130 may include a printed circuit board 3131 and a light source 3132. Particularly, the light source 3132 may be provided as a side view type light emitting device mounted on a side surface adjacent to a light emitting surface.

The optical sheet 3200 may be disposed between the light guide panel 3140 and the image display panel 3300, and include different kinds of sheets such as a diffusion sheet, a prism sheet, and a protection sheet.

The image display panel 3300 may display image, using light coming from the optical sheet 3200. The image display panel 3300 may include an array substrate 3320, a liquid crystal layer 3330, and a color filter substrate 3340. The array substrate 3320 may include pixel electrodes arranged in the matrix form, thin-film transistors applying driving voltage to the pixel electrodes, and signal lines provided to operate the thin-film transistors. The color filter substrate 3340 may include a transparent substrate, a color filter, and a common electrode. The color filter 3340 may include a filter provided so that a specific wavelength of light, among white light emitted from the backlight unit 3100, can pass therethrough. The liquid crystal layer 3330 may be rearranged by an electric field formed between the pixel electrodes and the common electrodes, to adjust light transmittance. As light passing through the liquid crystal layer 3330 passes through the color filter of the color filter substrate 3340, an image may be displayed. The image display panel 3300 may further include a driver circuit unit processing an image signal and the like.

In the display device 3000, the light sources 3132 may be configured to emit blue light, green light, and red light, and may have a relatively small half-width. Thus, after an emitted light passes through the color filter substrate 3340, blue light, green light, and red light, having relatively high color purity, may be implemented. In one embodiment, at least one of the light sources 3132 may be provided as any of the light sources described herein.

FIG. 23 is a perspective view illustrating a flat panel lighting device employing a semiconductor light emitting device package, according to an example embodiment of the present inventive concept.

Referring to FIG. 23, a flat panel lighting device 4100 may include a light source module 4110, a power supplying device 4120, and a housing 4030.

The light source module 4110 may include a light emitting device array as a light source, and the power supplying device 4120 may include a light emitting device driving unit.

The light source module 4110 may include a light emitting device array and be formed to have an entirely planar shape. The light emitting device array may include light emitting devices and a controller storing driving information for the light emitting devices. In one embodiment, at least one of the light emitting devices may be provided as any of the semiconductor light emitting device packages described herein.

The power supplying device 4120 may be configured to supply power to the light source module 4110. The housing 4130 may have a space to accommodate the light source module 4110 and the power supplying device 4120. The housing 4130 may be formed in a hexahedral shape having an open side surface, but is not limited thereto. The light source module 4110 may be arranged to emit light to the open side surface of the housing 4130.

FIG. 24 is an exploded perspective view schematically illustrating a bulb-type lamp as a lighting device including a semiconductor light emitting device package, according to an example embodiment of the present inventive concept.

Referring to FIG. 24, a lighting device 4200 may include a socket 4210, a power supply unit 4220, a heat radiating unit 4230, a light source module 4240, and an optical unit 4250. The light source module 4240 may include a light emitting device array, and the power supply unit 4220 may include a light emitting device driving unit.

The socket 4210 may be formed so that the lighting device 2400 may replace a conventional lighting device. Power may be applied to the lighting device 4200 through the socket 4210. As illustrated, the power supply unit 4220 may be configured of a first power supply unit 4221 and a second power supply unit 4222. The heat radiating unit 4230 may include an internal heat radiating unit 4231 and an external heat radiating unit 4232. The internal heat radiating unit 4231 may be directly connected to the light source module 4240 and/or the power supply unit 4220, such that heat may be transferred to the external heat radiating unit 4232. The optical unit 4250 may include an internal optical unit (not illustrated) and an external optical unit (not illustrated), and may be configured so that light emitted by the light source module 4240 can be uniformly emitted.

The light source module 4240 may receive power from the power supply unit 4220 to emit light to the optical unit 4250. The light source module 4240 may include one or more light emitting devices 4241, a circuit board 4242, and a controller 4243. In one embodiment, at least one of the light emitting devices 4241 may be provided as any of the semiconductor light emitting device packages described herein. The controller 4243 may store driving information of the light emitting devices 4241.

FIG. 25 is an exploded perspective view schematically illustrating a lamp including a communications module and a semiconductor light emitting device package, according to an example embodiment of the present inventive concept.

Referring to FIG. 25, a lighting device 4300 is different from the lighting device 4200 of FIG. 24 in that the lighting device 4300 may include a reflective panel 4310 above a light source module 4240. The reflective panel 4310 may evenly reflect light from a light source in a sideward direction and a rearward direction to reduce dazzle therefrom.

A communications module 4320 maybe installed above the reflective panel 4310 to implement home-network communications. For example, the communications module 4320 may be provided as a wireless communications module using Zigbee, Wi-Fi, Li-Fi, etc. On/off switching, brightness and the like of lighting devices installed in the interior and on the exterior of homes may be controlled by the communications module 4320 through a smartphone or a remote control unit. In addition, electronic appliances and automobile systems such as TVs, refrigerators, air conditioners, door locks, automobiles, and the like may be controlled through a Li-Fi communications module using a visible light of light of the lighting devices installed in the interior and on the exterior of homes.

The reflective panel 4310 and the communications module 4320 may be covered by a cover unit 4330.

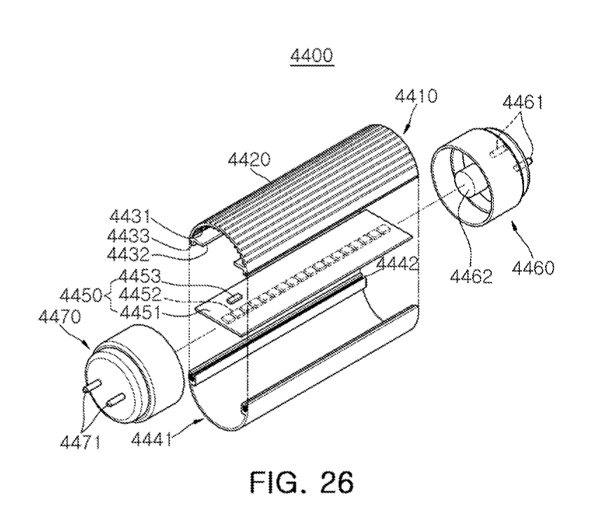

FIG. 26 is an exploded perspective view schematically illustrating a bar-type lamp employing a semiconductor light emitting device package, according to an example embodiment of the present inventive concept.

Referring to FIG. 26, a lighting device 4400 may include a heat-radiating member 4410, a cover 4441, a light source module 4450, a first socket 4460, and a second socket 4470. A plurality of heat-radiating fins 4420 and 4431 may be formed in concave-convex form on an internal surface and/or an external surface of the heat-radiating member 4410 to have various forms and intervals. A support 4432 having a form of a protuberance may be formed on an internal surface of the heat-radiating member 4410. The light source module 4450 may be fixed to the support 4432. Projections 4433 may be formed on both ends of the heat-radiating member 4410.

A groove 4442 may be formed in the cover 4441, and the projection 4433 of the heat-radiating member 4410 may engage with the groove 4442 in a hook-coupling structure. The positions of the groove 4442 and the projection 4433 may be interchanged with each other.

The light source module 4450 may include a light emitting device array. The light source module 4450 may include a printed circuit substrate 4451, light sources 4452, and a controller 4453. In one embodiment, at least one of the light sources 4452 may be provided as any of the light sources described herein. The controller 4453 may store driving information of the light source 4452. Circuit wirings for operating the light sources 4452 may be formed in the printed circuit substrate 4451. In addition, elements for the operating of the light source 4452 may be included in the printed circuit substrate 4451.

The first socket 4460 and the second socket 4470, as a pair of sockets, may engage with both ends of a cylindrical cover unit configured of the heat-radiating member 4410 and the cover 4441. For example, the first socket 4460 may include an electrode terminal 4461 and a power-supplying device 4462, and the second socket 4470 may include a dummy terminal 4471. In addition, alight sensor and/or a communications module may be built in any one of the first socket 4460 and the second socket 4470. For example, a light sensor and/or a communications module may be built in the second socket 4470 having the dummy terminal 4471. Moreover, a light sensor and/or a communications module may be built in the first socket 4460 including the electrode terminal 4461.

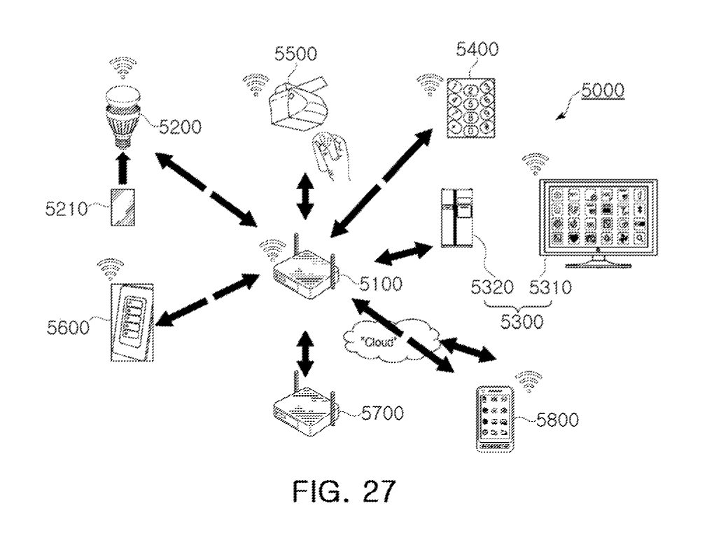

FIG. 27 is a view schematically illustrating a network system controlling an indoor lighting apparatus employing a semiconductor light emitting device package, according to an example embodiment of the present inventive concept.

Referring to FIG. 27, a network system 5000 may be provided as a comprehensive smart lighting-network system in which lighting technology using a light emitting device such as LED or the like, Internet of Things (IoT) technology, wireless communications technology, and the like are integrated. The network system 5000 may be implemented using various lighting devices and wired-wireless communications devices, and implemented by a sensor, a controller, a means of communications, software provided to control and maintain a network, and the like.

The network system 5000 may be applied to open spaces such as parks, streets, and the like, as well as to closed spaces defined in buildings such as homes and offices. The network system 5000 may be implemented based on an IoT environment, to collect and process various kinds of information and provide users with the information. Here, an LED lamp 5200 included in the network system may receive information about surrounding environment from a gateway 5100 to control the LED lamp 5200 itself. In addition, the LED lamp 5200 may also serve to check operations of other devices 5300 to 5800 included in the IoT environment and control the devices 5300 to 5800, based on functions of the LED lamp 5200 such as visible light communications and the like.

Referring to FIG. 27, the network system 5000 may include the gateway 5100 provided to process data transmitted and received according to different communications protocols, the LED lamp 5200 connected to communicate with the gateway 5100 and including an LED light emitting device, and a plurality of the devices 5300 to 5800 connected to communicate with the gateway 5100 according to various wireless communications methods. Each of the devices 5300 to 5800 as well as the LED lamp 5200 may include at least one communications module to implement the network system 5000 based on the IoT environment. The LED lamp 5200 may be connected to communicate with the gateway 5100 through a wireless communications protocol such as WiFi, Zigbee, Li-Fi, and the like. To this end, the LED lamp 5200 may include at least one communications module for lamp 5210.

As described above, the network system 5000 may be applied to open spaces such as streets and parks as well to closed spaces such as homes and offices. When the network system 5000 is applied to homes, the plurality of devices 5300 to 5800 included in the network system 5000 and connected to communicate with the gateway 5100 based on the IoT technology may include a home appliance 5300 such as a television 5310 and a refrigerator 5320, a digital door lock 5400, a garage door lock 5500, lighting switch 5600 installed on walls and the like, a router 5700 provided for a wireless communications network relay, a mobile device such as a smartphone, a table PC, a laptop computer, and the like.

In the network system 5000, the LED lamp 5200 may check operation of the devices 5300 to 5800 using wireless communications networks (Zigbee, WiFi, Li-Fi, etc.) installed in homes, or automatically control a level of luminance of the LED lamp 5200 itself according to a surrounding environment/condition. In addition, the LED lamp 5200 may control the devices 5300 to 5800 included in the network system 5000, using Li-Fi communications employing visible light emitted therefrom.

First, the LED lamp 5200 may automatically control a level of luminance thereof, based on information regarding the surrounding environment transmitted by the gateway 5100 and collected by a sensor installed in the LED lamp 5200. For example, a level of luminance of the LED lamp 5200 may be automatically controlled according to the types of programs broadcast on the television 5310 or a level of luminance of a screen thereof. For this, the LED lamp 5200 may receive operation information of the television 5310 from the communications module for lamp 5210 connected to the gateway 5100. The communications module for lamp 5210 may be modularized integrally with a sensor and/or a controller included in the LED lamp 5200.

For example, when a soap opera is broadcast on TV, light temperature may be decreased to 12000K or below, or for example, to 5000K, and a color feeling may be adjusted according to a preset setup value, such that a comfortable mood may be set. On the other hand, when a comedy program is broadcast on TV, the network system 5000 may be set so that light temperature can be increased to 5000K or higher, and a feeling of color may be adjusted by blue-enriched white lighting.

In addition, when a predetermined period of time has passed after the digital door lock 5400 was locked with nobody at home, the turned-on LED lamp 5200 may be turned off so that waste of electricity may be prevented. When the digital door lock 5400 is locked with nobody at home and a security mode is turned on through the mobile device 5800 and the like, the LED lamp 5200 may be kept turned-on.

Operations of the LED lamp 5200 may be controlled according to a surrounding environment of which information is collected by various sensors connected to the network system 5000. For example, when the network system 5000 is implemented in a building, a lighting device may be integrally combined with a positional sensor and the communications module, and positional information of people in the building may be collected, such that the lighting device may be turned on or off, or the collected information may be provided in real time. Thus, facility and unused space in the building may be efficiently managed. Since lighting devices such as the LED lamp 5200 may be generally installed in almost every space on every floor of a building, various types of information regarding the building may be collected by the sensor provided integrally with the LED lamp 5200 and used to manage facility, unused space, and the like.

The LED lamp 5200 combined with an image sensor, a storage device, the communications module for lamp 5210, and the like may be used as a device to maintain security of the building or to detect an emergency situation so that the situation is dealt with. For example, when a smoke detector or a temperature detector is attached to the LED lamp 5200, fire may be rapidly detected, such that damage from the fire may be significantly reduced. In addition, a level of brightness of the LED lamp 5200 may be adjusted according to weather or the amount of sunshine, such that energy consumption maybe reduced and a pleasant lighting environment may be provided.

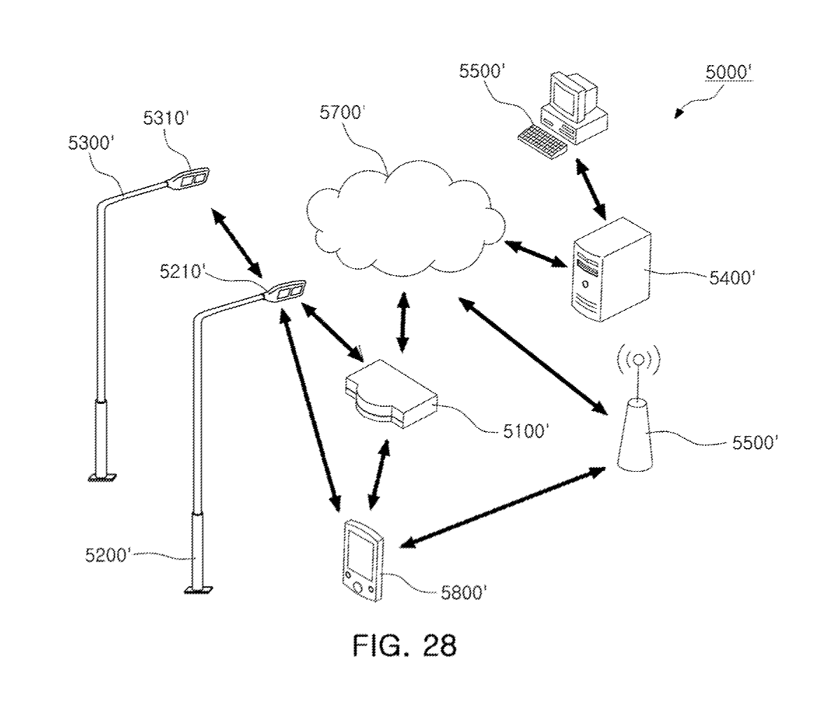

FIG. 28 is a view schematically illustrating an open network system employing a semiconductor light emitting device package, according to an example embodiment of the present inventive concept.

Referring to FIG. 28, a network system 5000′ may include a communications link device 5100′, a plurality of lighting devices 5200′ and 5300′ installed at regular intervals and connected to communicate with the communications link device 5100′, a server 5400′, a computer 5500′ provided to manage the server 5400′, a communications station 5600′, a communications network 5700′ connecting the above-mentioned devices able to communicate, and a mobile device 5800′.

The plurality of lighting devices 5200′ and 5300′ installed in an open outdoor spaces such as streets or parks may respectively include smart engines 5210′ and 5310′. The smart engines 5210′ and 5310′ may include a sensor collecting information about surrounding environment, a communications module, and the like, as well as a light emitting device to generate light and a driving driver provided to drive the light emitting device. The smart engines 5210′ and 5310′ may communicate with other devices using a communications protocol such as WiFi, Zigbee, Li-Fi, and the like through the communications module.

For example, a smart engine 5210′ may be connected to communicate with another smart engine 5310′. Here, a WiFi mesh technology may be applied to the communications between the smart engines 5210′ and 5310′. At least one smart engine 5210′ may be connected to the communications link device 5100′ connected to the communications network 5700′ through wired/wireless communications. Several smart engines 5210′ and 5310′ may be bound into one group to be connected to a single communications link device 5100′ in order to improve communications efficiency.

The communications link device 5100 may be provided as an access point (AP) connected through wired/wireless communications, thereby intermediating communications between the communications network 5700′ and other devices. The communications link device 5100′ may be connected to the communications network 5700′ through at least one of wired communications and wireless communications, and mechanically stored in, for example, at least one of the lighting devices 5200′ and 5300′.

The communications link device 5100′ may be connected to the mobile device 5800′ through a communications protocol such as WiFi and the like. The mobile device 5800′ may receive information about surrounding environment collected by the plurality of smart engines 5210′ and 5310′ through the communications link device 5100′ connected to the smart engine 5210′ of an adjacent lighting device 5200′. The information about surrounding environment may include surrounding traffic information, weather information, and the like. The mobile device 5800′ may be connected to the communications network 5700′ through the communications station 5600′ in a way of wireless cellular communications such as 3G and 4G.

The sever 5400′ connected to the communications network 5700′ may receive information collected by the smart engines 5210′ and 5310′ respectively installed in the lighting devices 5200′ and 5300′, while monitoring operation of the lighting devices 5200′ and 5300′. The server 5400′ may be connected to the computer 5500′ providing a management system to manage the respective lighting devices 5200′ and 5300′ based on monitoring results of operation of the respective lighting devices 5200′ and 5300′. The computer 5500′ may execute a software able to monitor and manage operation of the respective lighting devices 5200′ and 5300′, or in particular, the smart engines 5210′ and 5310′.

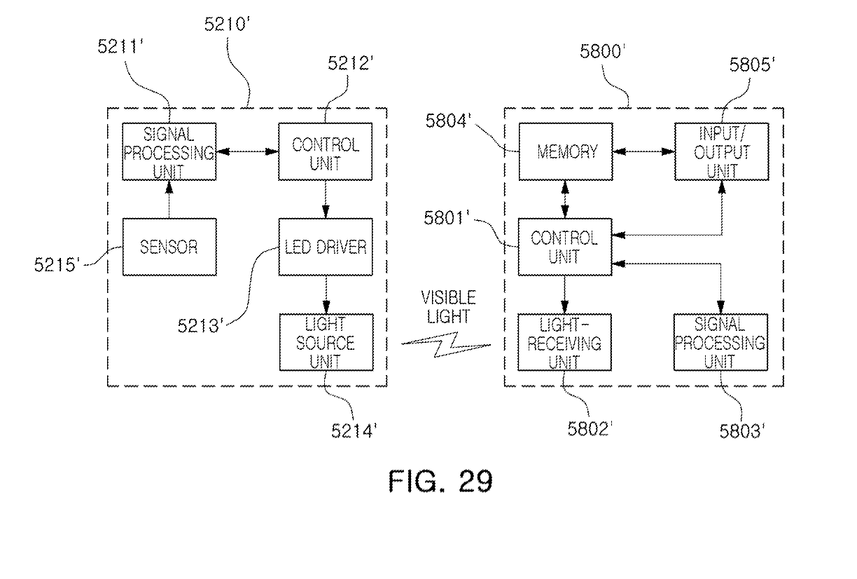

FIG. 29 is a block diagram illustrating communications between the smart engine and the mobile device of FIG. 28.

Referring to FIG. 29, the smart engine 5210′ may include a signal processing unit 5211′, a control unit 5212′, an LED driver 5213′, a light source unit 5214′, a sensor 5215′, and the like. The mobile device 5800′ connected to the smart engine 5210′ through Li-Fi may include a control unit 5801′, a light-receiving unit 5802′, a signal processing unit 5803′, a memory 5804′, an input/output unit 5805′, and the like.

Li-Fi technology is a wireless communications technology able to wirelessly transmit information using visible light visible to the human eye. Such Li-Fi technology may be different from wired optical communications technology and infrared wireless communications technology, in that Li-Fi technology may use visible light, or in other words, a specific wavelength of visible light emitted from any light emitting device package as exemplarily described above. In addition, Li-Fi technology may be different from the wired optical communications technology in that Li-Fi technology is a wireless communications technology. Further, Li-Fi technology, unlike RF wireless communications technology, may not be affected by regulations, and permission for the use thereof may not be required, and thus the Li-Fi technology may be relatively freely used. Thus, the Li-Fi technology may have great convenience and excellent physical security. The Li-Fi technology may have a distinct characteristic in that a communications link thereof may be seen with human eyes. Most of all, the Li-Fi technology has a characteristic of a fusion technology in that the purpose of a light source and a communications function may be simultaneously obtained.

The signal processing unit 5211′ of the smart engine 5210′ may process data to be transmitted and received through Li-Fi. In one embodiment, the signal processing unit 5211′ may transform information collected by the sensor 5215′ into data and transmit the data to the control unit 5212′. The control unit 5212′ may control operation of the signal processing unit 5211′, the LED driver 5213′, and the like, and especially operation of the LED driver 5213′ based on the data transmitted by the signal processing unit 5211′. The LED driver 5213′ may make the light source unit 5214′ emit light according to a control signal transmitted by the control unit 5212′, thereby transmitting the data to the mobile device 5800′.

The mobile device 5800′ may include the light-receiving unit 5802′ provided to recognize visible light having data, as well as the control unit 5801′, the memory 5804′ storing data, the input/output unit 5805′ including a display, a touch screen, an audio output unit, and the like, and the signal processing unit 5803′. The light-receiving unit 5802′ may recognize visible light and transform the visible light into an electrical signal. The signal processing unit 5803′ may decode data included in the above-mentioned electrical signal. The control unit 5801′ may store the data decoded by the signal processing unit 5803′ in the memory 5804′, or output the data to the input/output unit 5805′ so that users can recognize the data.

As set forth above, light extraction efficiency of a semiconductor light emitting device package may be improved when the semiconductor light emitting device package is manufactured using the methods of manufacturing a semiconductor light emitting device package as exemplarily described above.

While example embodiments have been shown and described above, it will be apparent to those skilled in the art that modifications and variations could be made without departing from the scope of the present invention as defined by the appended claims.

What is claimed is:

1. A method of manufacturing a semiconductor light emitting device package, comprising:
forming a plurality of light emitting diode chips having a first conductivity-type semiconductor layer, an active layer, and a second conductivity-type semiconductor layer sequentially stacked on a substrate;
forming a phosphor layer and an encapsulation layer on the first conductivity-type semiconductor layer;
forming a texture on the encapsulation layer by etching an upper surface of the encapsulation layer; and
separating the plurality of light emitting diode chips from each other.

2. The method of claim 1, wherein the texture is formed using a dry etching process.

3. The method of claim 1, wherein the forming of the phosphor layer and the encapsulation layer includes forming the phosphor layer on the first conductivity-type semiconductor layer and forming the encapsulation layer on the phosphor layer.

4. The method of claim 3, further comprising forming a transparent insertion layer on the first conductivity-type semiconductor layer before the forming of the phosphor layer, wherein a refractive index of the transparent insertion layer is larger than a refractive index of the phosphor layer, and smaller than a refractive index of the first conductivity-type semiconductor layer.

5. The method of claim 3, wherein a ratio of a thickness of the encapsulation layer to the phosphor layer ranges from 1:2 to 1:4.

6. The method of claim 1, wherein the forming of the phosphor layer and the encapsulation layer include forming the encapsulation layer on the first conductivity-type semiconductor layer and forming the phosphor layer on the encapsulation layer.

7. The method of claim 6, wherein an upper surface of the phosphor layer has a shape substantially the same as a shape of an upper surface of the encapsulation layer.

8. The method of claim 6, wherein a ratio of a thickness of the phosphor layer to the encapsulation layer ranges from 1:2 to 1:4.

9. The method of claim 1, wherein the phosphor layer includes a first phosphor layer disposed on the first conductivity-type semiconductor layer and a second phosphor layer disposed on the first phosphor layer, and wherein a wavelength of light convertable by the first phosphor layer is longer than a wavelength of light convertable by the second phosphor layer.

10. The method of claim 9, wherein the plurality of light emitting diode chips are configured to emit blue light, the first phosphor layer is configured to emit red light, and the second phosphor layer is configured to emit green light.

11. The method of claim 9, wherein a thickness of the first phosphor layer is smaller than a thickness of the second phosphor layer, and the first phosphor layer has an upper surface having a concave-convex portion.

12. The method of claim 1, wherein the phosphor layer includes a first phosphor layer disposed on the first conductivity-type semiconductor layer, a second phosphor layer disposed on the first phosphor layer, and a third phosphor layer disposed on the second phosphor layer, wherein a wavelength of light convertable by the first phosphor layer is longer than a wavelength of light convertable by the second phosphor layer, and a wavelength of light convertable by the second phosphor layer is longer than a wavelength of light convertable by the third phosphor layer.

13. The method of claim 12, wherein the plurality of light emitting diode chips are configured to emit ultraviolet light, the first phosphor layer is configured to emit red light, the second phosphor layer is configured to emit yellow light, and the third phosphor layer is configured to emit green light.

14. A method of manufacturing a semiconductor light emitting device package, comprising:
forming a plurality of light emitting diode chips having a first conductivity-type semiconductor layer, an active layer, and a second conductivity-type semiconductor layer sequentially stacked on a substrate;
forming a phosphor layer and an encapsulation layer on the first conductivity-type semiconductor layer;
forming a texture on an upper surface of the encapsulation layer using a blade; and
separating the plurality of light emitting diode chips from each other.

15. The method of claim 14, wherein the texture has a pyramidal shape.

16. A method of manufacturing a semiconductor light emitting device package, comprising:
forming a plurality of light emitting diode chips on a first substrate;
bonding a first surface of the plurality of light emitting diode chips to a second substrate;
removing the first substrate from the plurality of light emitting diode chips, thereby exposing a second surface of the plurality of light emitting diode chips, wherein the second surface is opposite the first surface;
forming a wavelength conversion material and an encapsulation layer on the second surface of the plurality of light emitting diode chips;
removing a portion of the material forming the encapsulation layer to form an encapsulation base layer and a plurality of patterns extending from the encapsulation base layer; and
separating the plurality of light emitting diode chips from each other, the separating including dividing the encapsulation base layer.

17. The method of claim 16, wherein the material of the encapsulation layer includes at least one selected from the group consisting of an epoxy resin and silicone.

18. The method of claim 17, wherein removing the portion of the material forming the encapsulation layer includes etching the encapsulation layer.

19. The method of claim 17, wherein removing the portion of the material forming the encapsulation layer includes cutting the encapsulation layer.

20. The method of claim 17, wherein forming the wavelength conversion material and the encapsulation layer comprises forming the wavelength conversion material after removing the portion of the material forming the encapsulation layer.
